(19) United States
(12) Patent Application Publication
(10) Pub. No.: US 2016/0149145 A1
(43) Pub. Date: May 26, 2016

(54) PEROVSKITES FOR OPTOELECTRONIC APPLICATIONS

(71) Applicant: NANYANG TECHNOLOGICAL UNIVERSITY, Singapore (SG)

(72) Inventors: Subodh Gautam MHAISALKAR, Singapore (SG); Thomas BAIKIE, Singapore (SG); Nripan MATHEWS, Singapore (SG); Pablo PEREZ BOIX, Singapore (SG); Cesare SOCI, Singapore (SG); Daniele CORTECCHIA, Singapore (SG)

(73) Assignee: NANYANG TECHNOLOGICAL UNIVERSITY, Singapore (SG)

(21) Appl. No.: 14/950,931

(22) Filed: Nov. 24, 2015

(30) Foreign Application Priority Data
Nov. 24, 2014 (SG) 10201407777S

(51) Int. Cl. H01L 51/00; H01L 51/42

(52) U.S. Cl. CPC H01L 51/0091; H01L 51/4206

(57) ABSTRACT

The invention relates generally to perovskite materials, and in particular, to copper perovskite materials. The invention further relates to solid-state integrated, lightweight, photovoltaic or light-emitting devices with an active layer based on the copper perovskite materials.

### CROSS-REFERENCE TO RELATED APPLICATION

This application claims the benefit of priority of Singapore Patent Application No. 10201407777S, filed Nov. 24, 2014, the contents of which being hereby incorporated by reference in its entirety for all purposes.

### TECHNICAL FIELD

The invention relates generally to perovskite materials, and in particular, to copper perovskite materials. The invention further relates to solid-state integrated, lightweight, photovoltaic or light-emitting devices with an active layer based on the copper perovskite materials.

### BACKGROUND

Organic-inorganic halide perovskite solar cells with efficiencies exceeding 17% have rapidly become the most efficient solution processed photovoltaic technology, leapfrogging other third generation photovoltaic technologies, which have been under development for decades. Such organic-inorganic halide perovskite solar cells present most of the advantages of classical dye sensitized solar cells (DSCs) such as low cost, solution processability and versatility.

Methylammonium lead iodide (CH₃NH₃PbI₃)—the primary semiconductor of interest—forms nearly defect free crystalline films at low temperatures and also exhibits long range balanced electron-hole transport lengths and high optical absorption coefficients, essential in optoelectronic applications. However, concerns with the toxicity of lead (Pb) necessitate the studies of alternative low temperature processable halide perovskite solar cells. As a consequence, there is a need to develop non-toxic and environmentally friendly perovskites, which can act as high efficiency photovoltaic absorbers or light harvesters.

### SUMMARY

The present invention shows immense advantage in using non-toxic copper perovskite as solar photovoltaic and light emission material. The development of this technology can result in optoelectronic devices possessing conventional lead perovskite advantages (i.e. high efficiency, solution processability, versatility, etc.) but avoiding their toxicity.

In this context, copper (Cu) based Ruddlesden-Popper series perovskites represent a key opportunity and perovskites based on Cu, such as (CH₃NH₃)₂CuBr₄, are targeted because of their excellent band gap and the possibility of stabilization of the Cu ionic states.

According to one aspect of the invention, there is provided a copper-based perovskite material comprising a general formula (I), (II), or (III),

(A1)ₐ(A2)_{b}Cu(X1)_{c}(X2)_{d}(X3)ₑ(X4)_{f} (I)

(A1)ₐ(A2)_{b}Cu(X1)_{c}(X2)_{d}(X3)ₑ(X4)_{f}(X5)_{g}(X6)ₕ (II)

(A1)ₐCu(X1)_{b}(X2)_{c}(X3)_{d} (III)
wherein in formula (I):
A1 and A2 are independently selected from the group consisting of an organic ammonium cation derived from RNH₃ wherein R is an aliphatic group, a cyclic group, or an aromatic group; an organic cation derived from an aromatic compound, and an inorganic cation comprising Li⁺, Na⁺, K⁺, Rb⁺ or Cs⁺; X1, X2, X3, and X4 are independently a halide selected from the group consisting of Cl⁻, Br⁻, F and I⁻, or an oxygen-halide;
a+b=2;
c+d+e+f=4;
wherein in formula (II): A1 and A2 are independently selected from the group consisting of an organic ammonium cation derived from RNH₃ wherein R is an aliphatic group, a cyclic group, or an aromatic group; an organic cation derived from an aromatic compound, and an inorganic cation comprising Li⁺, Na⁺, K⁺, Rb⁺ or Cs⁺; X1, X2, X3, X4, X5, and X6 are independently a halide selected from the group consisting of Cl⁻, Br⁻, F and I⁻, or an oxygen-halide;
a+b=2;
c+d+e+f+g+h=6.
wherein in formula (III):
A1 is selected from the group consisting of an organic ammonium cation derived from RNH₃ wherein R is an aliphatic group, a cyclic group, or an aromatic group; an organic cation derived from an aromatic compound, and an inorganic cation comprising Li⁺, Na⁺, K⁺, Rb⁺ or Cs⁺;
X1, X2, and X3 are independently a halide selected from the group consisting of Cl⁻, Br⁻, F and I⁻, or an oxygen-halide;
a=1;
b+c+d=3.

According to another aspect of the invention, there is disclosed an optoelectronic device, comprising:
an active layer comprising a copper-based perovskite material according to the earlier aspect, wherein the active layer is arranged in between a charge carrier transporting layer and a charge carrier blocking layer;
a conducting substrate; and
a current collector.

A further aspect of the invention relates to a method of synthesizing a copper-based perovskite material according to an earlier aspect, the method comprising:
dissolving a precursor of the organic ammonium cation, organic cation or inorganic cation and copper halide or a Cu²⁺ based precursor in an alcohol;
heating the mixture for a period of time;
crystallizing the mixture in an ice-bath overnight to obtain the copper-based perovskite material crystals;
filtering the crystals; and
drying the crystals in an oven.

For example, the Cu²⁺ based precursor may be Cu(II) acetate Cu(OAc)₂.

In yet another aspect of the invention, a method of fabricating an optoelectronic device according to an earlier aspect is described. The method comprises:
arranging an active layer comprising a copper-based perovskite material according to an earlier aspect in between a charge carrier transporting layer and a charge carrier blocking layer;
arranging a conducting substrate in contact with the charge carrier blocking layer; and arranging a current collector in contact with the charge carrier transporting layer.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1A-B shows an example of band gap determination through the Tauc Plots constructed from the absorption measurement on thin film of copper perovskites: (CH₃NH₃)₂CuCl₂Br₂, offset ˜2.5 eV (FIG. 1A), and (CH₃NH₃)₂CuCl_{0.5}Br_{3.5}, offset ˜1.81 eV (FIG. 1B).

FIG. 2A shows absorption coefficient of a series of copper perovskite, showing the tuning of the optical properties of the material by changing the Cl/Br ratio and FIG. 2B shows absorption spectrum of CsCuCl₃.

FIG. 3A-D shows schematic representation of examples of photovoltaic devices 100 based on Cu-perovskite: mesoporous structure (FIG. 3A); thin film configuration (FIG. 3B); thin film configuration with inverted structure (FIG. 3C); general representation of the cross section of a solar cell device (FIG. 3D). In FIG. A, 10 represents a transparent conductive layer (such as fluoride doped tin oxide or an indium tin oxide layer); 20 represents a plastic or glass substrate; 30 represents a compact titanium dioxide (TiO₂) layer; 40 represents a mesoscopic TiO₂ layer loaded with Cu-perovskite; 50 represents a hole transport layer (such as spiro-OMeTAD or CuSCN layer); 60 represents a metal contact; 70 represents anode metal contact. In FIG. 3B, 10 represents a transparent conductive layer; 20 represents a plastic or glass substrate; 30 represents a compact n-type semiconductor layer; 40 represents a mesoscopic n-type semiconductor layer loaded with Cu-perovskite or Cu-perovskite thin film; 50 represents hole transport layer; 60 represents a metal contact; 70 represents metal contact. In FIG. 3C, 10 represents a transparent conductive layer; 20 represents a plastic or glass substrate; 30 represents a compact p-type semiconductor layer; 40 represents a mesoscopic p-type semiconductor layer loaded with Cu-perovskite or Cu-perovskite thin film; 50 represents electron transport layer (such as PCBM or ZnO layer); 60 represents a metal contact; 70 represents metal contact. In FIG. 3D, 30 represents a compact hole blocking or electron blocking layer; 40 represents a mesoscopic p-type or n-type semiconductor layer loaded with Cu-perovskite or Cu-perovskite thin film; 50 represents hole transport or electron transport layer; 60 represents a metal contact; 70 represents a conducting substrate.

FIG. 4 shows cross section of a solar cell device with structure “compact TiO₂/mesoporous TiO₂/(CH₃NH₃)₂CuCl₂Br₂ perovskite/spiro-OMeTAD/gold”.

FIG. 5A-B shows pictures of solar cells based on (CH₃NH₃)₂CuCl₂Br₂ (FIG. 5A), and (CH₃NH₃)₂CuCl_{0.5}Br_{3.5} (FIG. 5B).

FIG. 6 shows powder XRD of copper perovskite with general formula (CH₃NH₃)₂CuClₓBr₄₋ₓ crystallized from ethanol. Crystal system: Orthorombic, Space Group: Acam, lattice constants for (CH₃NH₃)₂CuCl₂Br₂ a=7.338 Å; b=7.338 Å; c=19.187 Å, for (CH₃NH₃)₂CuClBr₃ a=7.396 Å; b=7.367 Å; c=19.321 Å, for (CH₃NH₃)₂CuCl_{0.5}Br_{3.5} a=7.428 Å; b=7.469 Å; c=19.308 Å.

FIG. 7A shows cross section of mesoporous TiO₂ infiltrated with the perovskite (CH₃NH₃)₂CuCl_{0.5}Br_{3.5}; and FIG. 7B shows relative EDX spectrum confirming the presence of Cu, Br and Cl within the TiO₂ scaffold.

FIG. 8A shows XRD pattern of (CH₃NH₃)₂CuCl₂Br₂ powders and thin film deposited on glass; FIG. 8B shows thin film XRD of CsCuCl₃.

FIG. 9 shows photocurrent measurement made on a device sensitized with (CH₃NH₃)₂CuCl₂Br₂.

FIG. 10 shows an example of photovoltaic performance with a device having a structure mesoporous TiO₂/(CH₃NH₃)₂CuBr₂Cl₂/spiro-OMeTAD. The copper perovskite (CH₃NH₃)₂CuBr₂Cl₂ is acting as a light harvester.

FIG. 11A-B shows an example of photovoltaic performance with a device having structure mesoporous TiO₂/(CH₃NH₃)₂CuBr₄/spiro-OMeTAD (FIG. 11A) and mesoporous TiO₂/CsCuCl₃/spiro-OMeTAD (FIG. 11B). The copper perovskite (CH₃NH₃)₂CuBr₄ and CsCuCl₃ are acting as light harvesters.

FIG. 12A-C shows XRD characterization of 2D copper-based perovskites: powder XRD of MA₂CuCl₄, MA₂CuCl₂Br₂, MA₂CuClBr₃, and MA₂CuCl_{0.5}Br_{3.5} (FIG. 12A); crystal structure of MA₂CuCl₂Br₂, showing the alternation of organic and inorganic layers (FIG. 12B); thin film XRD of MA₂CuCl₂Br₂ (upper panel) and MA₂CuCl_{0.5}Br_{3.5} (lower panel) compared to their respective powders, showing strong preferential orientation towards the 002 direction (FIG. 12C).

FIG. 13A shows absorption coefficient for perovskites of the series MA₂CuClₓBr₄₋ₓ showing strong CT bands below 650 nm and broad d-d transitions between 700 nm and 900 nm (inset); FIG. 13B shows representation of the electronic transitions for MA₂CuCl₂Br₂: charge transfer transitions 1 and 2 (Cl, Br_pσ→Cu_dₓ_{²}_{-y}_{²} and Cl, Br_pπ→Cu_dₓ_{²}_{-y}_{²}) and d-d transitions 3 (Cu_d_{xy}→Cu_dₓ_{²}_{-y}_{²}); FIG. 13C shows color shift for powders with different Br/Cl ratio: MA₂CuCl₄, MA₂CuCl₂Br₂, MA₂CuCl_{0.5}Br_{3.5}.

FIG. 14A-D shows an electronic band structure and density of states of the four copper pervoskite compounds investigated by DFT simulations: MA₂CuCl₄ (FIG. 14A), MA₂CuCl₂Br₂ (FIG. 14B), MA₂CuClBr₃ (FIG. 14C), and MA₂CuCl_{0.5}Br_{3.5} (FIG. 14D).

FIG. 15A shows an exploded view of solar cell devices based on mesoporous TiO₂ sensitized with the perovskite MA₂CuClₓBr₄₋ₓ; FIG. 15B shows energy dispersive X-ray spectra (EDX) line scan on the cross section of a mesoporous TiO2 layer (5 mm), showing the homogeneous infiltration with 2D copper perovskite along all the film depth.

FIG. 16A shows IV curve of solar cells sensitized with MA₂CuCl₂Br₂ (red) and MA₂CuCl_{0.5}Br_{3.5} (brown) under 1 sun light illumination; FIG. 16B shows photocurrent measurement performed on a device sensitized with MA₂CuCl₂Br₂ (upper panel) compared to the perovskite absorption spectrum.

FIG. 17A shows recombination resistance and FIG. 17B shows chemical capacitance extracted from the fitting of the IS spectra measured under 1 sun illumination.

FIG. 18 shows XRD study with increasing Br/Cl ratio in Cu-perovskite. Due to the bigger ionic radius of Br compared to Cl, the increase in Br/Cl ratio augments the unit cell dimensions, resulting in progressive peak shift to lower diffraction angles with Br addition from MA₂CuCl₄ to MA₂CuCl_{0.5}Br_{3.5}.

FIG. 19A-B shows thermogravimetric analysis (TGA) of MA₂CuCl₂Br₂ (FIG. 19A) to MA₂CuCl_{0.5}Br_{3.5} (FIG. 19B), respectively. The decomposition profile proceeds with two steps, and the first weight loss increases with higher Br content, indicating a major loss of Br compounds during this step, such as MABr and HBr, together with the release of MACl and HCl and CH₃NH₂. At higher temperatures, the decomposition is possibly accompanied with the formation of higher boiling point compounds such as CuCl₂.

FIG. 20 shows annealing study of MA₂CuCl_{0.5}Br_{3.5} films at 100° C. resulting in the loss of peaks characteristic of perovskites, and extra peaks appear between 10° and 30°. Samples annealed at 70° C. for 30 min display residual MABr which is minimized with prolonged annealing at 70° C. for 1 h.

FIG. 21 shows Tauc Plot construction for the determination of perovskite's direct band gap associated to CT transitions.

FIG. 22 shows binding energy (BE) and work function (WF) determination for MA₂CuCl₂Br₂ and MA₂CuCl_{0.5}Br_{3.5} by ultraviolet photoelectron spectroscopy (UPS). FIG. 23 shows a comparison between experimental and simulated band gap data. The calculated excitonic band gap matches with the value of the CT transition determined from absorption spectra. Both experimental results and simulated data indicate the same trend in terms of decreasing band-gaps with increasing Br/Cl ratio.

FIG. 24A-D shows projected density of states of the four copper pervoskite compounds MA₂CuCl₄ (FIG. 24A), MA₂CuCl₂Br₂ (FIG. 24B), MA₂CuClBr₃ (FIG. 24C), and MA₂CuCl_{0.5}Br_{3.5} (FIG. 24D) from DFT calculations.

FIG. 25A-D shows SEM images of mesoporous TiO₂ infiltrated with MA₂CuCl₂Br₂ using DMSO solution of different concentration: 1M (FIG. 25A, FIG. 25C) and 2M (FIG. 25B, FIG. 25D).

FIG. 26 shows copper perovskite-based solar cell with inverted structure PEDOT:PSS/MA₂CuCl₂Br₂/PCBM.

FIG. 27A-B shows X-Ray photoelectron spectroscopy (XPS) analysis of MA₂CuCl₂Br₂ and MA₂CuCl_{0.5}Br_{3.5}. In Cu 2p spectra, in pure bromine sample, no satellite peak suggests the surface of this sample changes to Cu⁺ (FIG. 27A). Samples with chlorine show satellite peaks, indicating the presence of Cu²⁺ ions (FIG. 27B).

FIG. 28A shows series resistance extracted from the fitting of the impedance spectrum measured under 1 sun; and FIG. 28B shows example of impedance spectra under 1 sun at 0.25 V for both analyzed samples, the inset represents the equivalent circuit employed for the fitting.

FIG. 29A shows absorption coefficient for perovskites of the series MA₂CuClₓBr₄₋ₓ showing strong CT bands below 650 nm and broad d-d transitions between 700 nm and 900 nm (inset); FIG. 29B shows photoluminescence of the perovskites MA₂CuClₓBr₄₋ₓ (λexc=310 nm) with intensity increasing with higher Br contents; FIG. 29C shows color shift for powders with different Br/Cl ratio: MA₂CuCl₄ (yellow), MA₂CuCl₂Br₂ (red), MA₂CuCl_{0.5}Br_{3.5} (dark brown).

FIG. 30 shows time resolved photoluminescence of the perovskite MA₂CuClₓBr₄₋ₓ with different Br/Cl ratios at excitation wavelength of 310 nm and probe at 525 nm.

FIG. 31A-D shows transient absorption spectrum of MA₂CuCl₄ (FIG. 31A) (λexc=500 nm) and ultrafast dynamics (λexc=500 nm, λprobe=620 nm) of MA₂CuCl₄ (FIG. 31B), MA₂CuCl₂Br₂ (FIG. 31C) and MA₂CuClBr₃ (FIG. 31D) with and without junction with TiO₂.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

The present disclosure presents the design of a light harvester material based on Cu-perovskite. Copper (Cu) is a suitable non-toxic, abundant and environmentally friendly option for the perovskite formation. These perovskites have the generic structure [A]Cu[X]₃ or [A]₂Cu[X]₄ (for Cu²⁺) or [A]₂Cu[X]₆ (for Cu⁴⁺) where A is an organic or inorganic cation and X is a halide or oxygen-halide mixture.

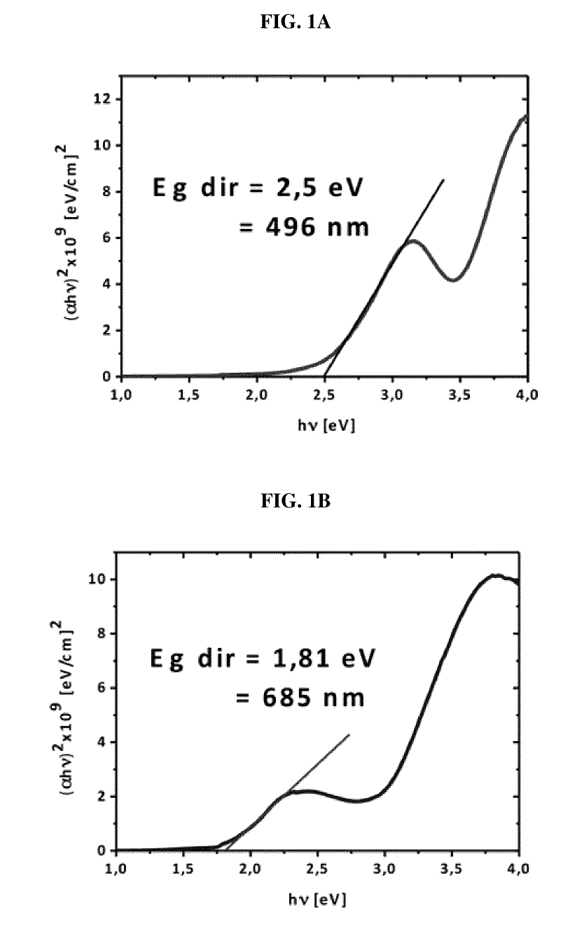

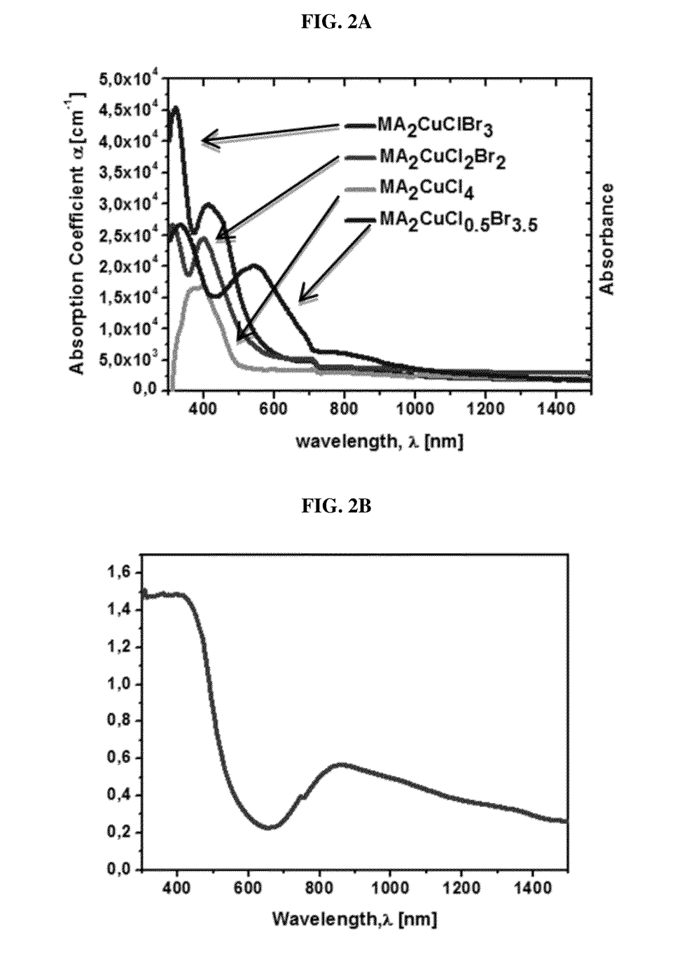

These perovskites, such as (CH₃NH₃)₂CuX₄, are suitable for light harvesting due to their band gaps ranging from less than 1.5 eV to more than 2.5 eV (see FIG. 1A-B) and high absorption coefficient up to 50000 cm⁻¹ (FIG. 2A); in FIG. 2B is shown as example the absorption spectrum of CsCuCl₃. The variation of cations and the halide tuning can modify the space between the different perovskite layers, which can result in an improvement of the electrical characteristics. For example, (CH₃NH₃)₂CuCl₄ forms a 2D layered perovskite structure; analogous to that adopted by the high temperature superconductor La₂₋ₓBaₓCuO₄. At room temperature (CH₃NH₃)₂CuCl₄ is shown to adopt a distorted monoclinic structure, which displays a band gap of 2.6 eV. Gradual replacement of Cl for Br (i.e. (CH₃NH₃)₂CuCl₄₋ₓBrₓ), leads to a less distorted orthorhombic/tetragonal structures with a corresponding reduction in band gap (CH₃NH₃)₂CuCl₂Br₂=2.5 eV; (CH₃NH₃)₂CuCl_{0.5}Br_{3.5}=1.81 eV). Additionally, the higher symmetry structures of the Br-rich phases leads to improved electronic transport properties, with the reduction in band gap. In addition, a judicious selection of organic component can give extra control of the interlayer spacings and offers an alternative approach to tailoring the physical properties of these materials.

Thus, according to one aspect, the Cu-perovskite material comprises a general formula (I), (II), or (III),

(A1)ₐ(A2)_{b}Cu(X1)_{c}(X2)_{d}(X3)ₑ(X4)_{f} (I)

(A1)ₐ(A2)_{b}Cu(X1)_{c}(X2)_{d}(X3)ₑ(X4)_{f}(X5)_{g}(X6)ₕ (II)

(A1)ₐCu(X1)_{b}(X2)_{c}(X3)_{d} (III)
wherein in formula (I):
A1 and A2 are independently selected from the group consisting of an organic ammonium cation derived from RNH₃ wherein R is an aliphatic group, a cyclic group, or an aromatic group; an organic cation derived from an aromatic compound, and an inorganic cation comprising Li⁺, Na⁺, K⁺, Rb⁺ or Cs⁺; X1, X2, X3, and X4 are independently a halide selected from the group consisting of Cl⁻, Br⁻, F and I⁻, or an oxygen-halide;
a+b=2;
c+d+e+f=4;
wherein in formula (II): A1 and A2 are independently selected from the group consisting of an organic ammonium cation derived from RNH₃ wherein R is an aliphatic group, a cyclic group, or an aromatic group; an organic cation derived from an aromatic compound, and an inorganic cation comprising Li⁺, Na⁺, K⁺, Rb⁺ or Cs⁺; X1, X2, X3, X4, X5, and X6 are independently a halide selected from the group consisting of Cl⁻, Br⁻, F and I⁻, or an oxygen-halide;
a+b=2;
c+d+e+f+g+h=6.
wherein in formula (III):
A1 is selected from the group consisting of an organic ammonium cation derived from RNH₃ wherein R is an aliphatic group, a cyclic group, or an aromatic group; an organic cation derived from an aromatic compound, and an inorganic cation comprising Li⁺, Na⁺, K⁺, Rb⁺ or Cs⁺;
X1, X2, and X3 are independently a halide selected from the group consisting of Cl⁻, Br⁻,
F and I⁻, or an oxygen-halide;
a=1;
b+c+d=3.

The term “aliphatic”, alone or in combination, refers to a straight chain or branched chain hydrocarbon comprising at least one carbon atom. Aliphatics include alkyls, alkenyls, and alkynyls. In certain embodiments, aliphatics are optionally substituted, i.e. substituted or unsubstituted. Aliphatics include, but are not limited to, methyl, ethyl, propyl, isopropyl, butyl, isobutyl, tert-butyl, pentyl, hexyl, ethenyl, propenyl, butenyl, ethynyl, butynyl, propynyl, and the like, each of which may be optionally substituted. As used herein, aliphatic is not intended to include cyclic groups.

The term “alkyl”, alone or in combination, refers to a fully saturated aliphatic hydrocarbon. In certain embodiments, alkyls are optionally substituted. In certain embodiments, an alkyl comprises 1 to 30 carbon atoms, for example 1 to 20 carbon atoms, wherein (whenever it appears herein in any of the definitions given below) a numerical range, such as “1 to 20” or “C₁-C₂₀”, refers to each integer in the given range, e.g. “C₁-C₂₀ alkyl” means that an alkyl group comprising only 1 carbon atom, 2 carbon atoms, 3 carbon atoms, etc., up to and including 20 carbon atoms. Examples of alkyl groups include, but are not limited to, methyl, ethyl, n-propyl, isopropyl, n-butyl, isobutyl, sec-butyl, tert-butyl, tert-amyl, pentyl, hexyl, heptyl, octyl and the like. In various embodiments, the organic ammonium cation may be CH₃NH₃⁺ or C₂H₅NH₃⁺.

The term “alkoxy”, alone or in combination, refers to an aliphatic hydrocarbon having an alkyl-O— moiety. In certain embodiments, alkoxy groups are optionally substituted. Examples of Alkoxy groups include, but are not limited to, methoxy, ethoxy, propoxy, butoxy and the like. In one embodiment, the organic ammonium cation may be 2,2-(ethylenedioxy)bis(ethylammonium) (EDBE).

The term “heteroaliphatic”, alone or in combination, refers to a group comprising an aliphatic hydrocarbon (such as alkyl, alkenyl, and alkynyl) and one or more heteroatoms. In certain embodiments, heteroaliphatics are optionally substituted, i.e. substituted or unsubstituted. Certain heteroaliphatics are acylaliphatics, in which the one or more heteroatoms are not within an aliphatic chain. Heteroaliphatics include heteroalkyls, including, but not limited to, acylalkyls, heteroalkenyls, including, but not limited to, acylalkenyls, and heteroalkynyls, including, but not limited acylalkynyls. Examples of heteraliphatics include, but are not limited to, CH₃C(═O)CH₂—, CH₃C(═O)CH₂CH₂—, CH₃CH₂C(═O)CH₂CH₂—, CH₃C(═O)CH₂CH₂CH₂—, CH₃OCH₂CH₂—, CH₃NHCH₂—, and the like.

The term “heterohaloaliphatic” refers to a heteroaliphatic in which at least one hydrogen atom is replaced with a halogen atom. Heterohaloaliphatics include heterohaloalkyls, heterohaloalkenyls, and heterohaloalkynyls In certain embodiments, heterohaloaliphatics are optionally substituted.

The term “carbocycle” refers to a group comprising a covalently closed ring, wherein each of the atoms forming the ring is a carbon atom. Carbocylic rings may be formed by three, four, five, six, seven, eight, nine, or more than nine carbon atoms. Carbocycles may be optionally substituted.

The term “heterocycle” refers to a group comprising a covalently closed ring wherein at least one atom forming the ring is a carbon atom and at least one atom forming the ring is a heteroatom. Heterocyclic rings may be formed by three, four, five, six, seven, eight, nine, or more than nine atoms. Any number of those atoms may be heteroatoms (i.e., a heterocyclic ring may comprise one, two, three, four, five, six, seven, eight, nine, or more than nine heteroatoms). Herein, whenever the number of carbon atoms in a heterocycle is indicated (e.g., C₁-C₆ heterocycle), at least one other atom (the heteroatom) must be present in the ring. Designations such as “C₁-C₆ heterocycle” refer only to the number of carbon atoms in the ring and do not refer to the total number of atoms in the ring. It is understood that the heterocylic ring will have additional heteroatoms in the ring. In heterocycles comprising two or more heteroatoms, those two or more heteroatoms may be the same or different from one another. Heterocycles may be optionally substituted. Binding to a heterocycle can be at a heteroatom or via a carbon atom. Examples of heterocycles include, but are not limited to the following:

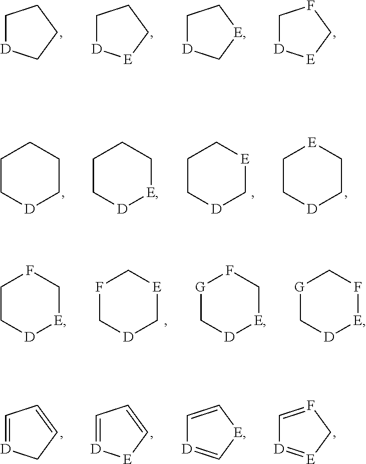

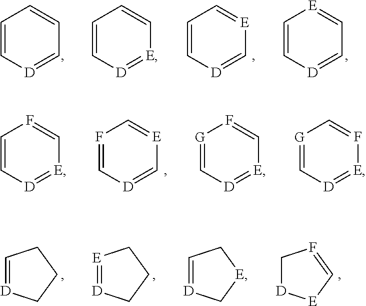

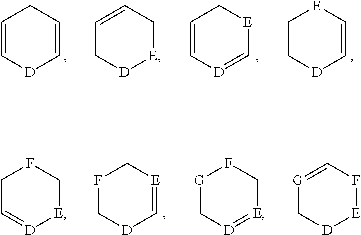

wherein D, E, F, and G independently represent a heteroatom. Each of D, E, F, and G may be the same or different from one another. In one embodiment, the organic ammonium cation may be N-(3-aminopropyl)imidazole (API).

The term “heteroatom” refers to an atom other than carbon or hydrogen. Heteroatoms are typically independently selected from oxygen, sulfur, nitrogen, and phosphorus, but are not limited to those atoms. In embodiments in which two or more heteroatoms are present, the two or more heteroatoms may all be the same as one another, or some or all of the two or more heteroatoms may each be different from the others.

The term “aromatic” refers to a group comprising a covalently closed planar ring having a delocalized [pi]-electron system comprising 4n+2 [pi] electrons, where n is an integer. Aromatic rings may be formed by five, six, seven, eight, nine, or more than nine atoms. Aromatics may be optionally substituted. Examples of aromatic groups include, but are not limited to phenyl, naphthalenyl, phenanthrenyl, anthracenyl, tetralinyl, fluorenyl, indenyl, and indanyl. The term aromatic includes, for example, benzenoid groups, connected via one of the ring-forming carbon atoms, and optionally carrying one or more substituents selected from an aryl, a heteroaryl, a cycloalkyl, a non-aromatic heterocycle, a halo, a hydroxy, an amino, a cyano, a nitro, an alkylamido, an acyl, a C₁-C₆ alkoxy, a C₁-C₆ alkyl, a C₁-C₆ hydroxyalkyl, a C₁-C₆ aminoalkyl, an alkylsulfenyl, an alkylsulfinyl, an alkylsulfonyl, an sulfamoyl, or a trifluoromethyl. In certain embodiments, an aromatic group is substituted at one or more of the para, meta, and/or ortho positions. Examples of aromatic groups comprising substitutions include, but are not limited to, phenyl, 3-halophenyl, 4-halophenyl, 3-hydroxyphenyl, 4-hydroxyphenyl, 3-aminophenyl, 4-aminophenyl, 3-methylphenyl, 4-methylphenyl, 3-methoxyphenyl, 4-methoxyphenyl, 4-trifluoromethoxyphenyl, 3-cyanophenyl, 4-cyanophenyl, dimethylphenyl, naphthyl, hydroxynaphthyl, hydroxymethylphenyl, (trifluoromethyl)phenyl, alkoxyphenyl, 4-morpholin-4-ylphenyl, 4-pyrrolidin-1-ylphenyl, 4-pyrazolylphenyl, 4-triazolylphenyl, and 4-(2-oxopyrrolidin-1-yl)phenyl. In one embodiment, the organic cation (i.e. without an ammonium moiety) may be a tropylium ion [C₇H₇]⁺.

The term “aryl” refers to an aromatic ring wherein each of the atoms forming the ring is a carbon atom. Aryl rings may be formed by five, six, seven, eight, nine, or more than nine carbon atoms. Aryl groups may be optionally substituted.

The term “heteroaryl” refers to an aromatic heterocycle. Heteroaryl rings may be formed by three, four, five, six, seven, eight, nine, or more than nine atoms. Heteroaryls may be optionally substituted. Examples of heteroaryl groups include, but are not limited to, aromatic C3-8 heterocyclic groups comprising one oxygen or sulfur atom or up to four nitrogen atoms, or a combination of one oxygen or sulfur atom and up to two nitrogen atoms, and their substituted as well as benzo- and pyrido-fused derivatives, for example, connected via one of the ring-forming carbon atoms. In certain embodiments, heteroaryl groups are optionally substituted with one or more substituents, independently selected from halo, hydroxy, amino, cyano, nitro, alkylamido, acyl, C1-6-alkoxy, C1-6-alkyl, C1-6-hydroxyalkyl, C1-6-aminoallcyl, alkylamino, alkylsulfenyl, alkylsulfinyl, alkylsulfonyl, sulfamoyl, or trifluoromethyl. Examples of heteroaryl groups include, but are not limited to, unsubstituted and mono- or di-substituted derivatives of furan, benzofuran, thiophene, benzothiophene, pyrrole, pyridine, indole, oxazole, benzoxazole, isoxazole, benzisoxazole, thiazole, benzothiazole, isothiazole, imidazole, benzimidazole, pyrazole, indazole, tetrazole, quinoline, isoquinoline, pyridazine, pyrimidine, purine and pyrazine, furazan, 1,2,3-oxadiazole, 1,2,3-thiadiazole, 1,2,4-thiadiazole, triazole, benzotriazole, pteridine, phenoxazole, oxadiazole, benzopyrazole, quinolizine, cinnoline, phthalazine, quinazoline, and quinoxaline.

The term “non-aromatic ring” refers to a group comprising a covalently closed ring that is not aromatic.

The term “alicyclic” refers to a group comprising a non-aromatic ring wherein each of the atoms forming the ring is a carbon atom. Alicyclic groups may be formed by three, four, five, six, seven, eight, nine, or more than nine carbon atoms. In certain embodiments, alicyclics are optionally substituted, i.e. substituted or unsubstituted. In certain embodiments, an alicyclic comprises one or more unsaturated bonds, such as one or more carbon-carbon double-bonds. Alicyclics include cycloalkyls and cycloalkenyls. Examples of alicyclics include, but are not limited to, cyclopropane, cyclobutane, cyclopentane, cyclopentene, cyclopentadiene, cyclohexane, cyclohexene, 1,3-cyclohexadiene, 1,4-cyclohexadiene, cycloheptane, and cycloheptene.

The term “non-aromatic heterocycle” refers to a group comprising a non-aromatic [pi]ng wherein one or more atoms forming the ring is a heteroatom Non-aromatic heterocyclic rings may be formed by three, four, five, six, seven, eight, nine, or more than nine atoms. Non-aromatic heterocycles may be optionally substituted In certain embodiments, non-aromatic heterocycles comprise one or more carbonyl or thiocarbonyl groups such as, for example, OXO- and thio-contammg groups Examples of non-aromatic heterocycles include, but are not limited to, lactams, lactones, cyclic lmides, cyclic thioimides, cyclic carbamates, tetrahydrothiopyran, 4H-pyran, tetrahydropyran, pipe[pi]dme, 1,3-dioxm, 1,3-dioxane, 1,4-dioxin, 1,4-dioxane, piperazme, 1,3-oxathiane, 1,4-oxathnn, 1,4-oxathiane, tetrahydro-1,4-thiazme, 2H-1,2-oxazme, maleimide, succimmide, barbituric acid, thiobarbituric acid, dioxopiperazine, hydantom, dihydrouracil, mo[phi]hohne, trioxane, hexahydro-1,3,5-triazine, tetrahydrothiophene, tetrahydrofuran, pyrrolme, pyrrolidine, pyrrohdone, pyrrohdione, pyrazohne, pyrazolidme, imidazoline, lmidazolidme, 1,3-dioxole, 1,3-dioxolane, 1,3-dithiole, 1,3-dithiolane, isoxazoline, lsoxazohdme, oxazolme, oxazolidme, oxazohdmone, thiazohne, thiazolidme, and 1,3-oxathiolane.

The term “arylalkyl” refers to a group comprising an aryl group bound to an alkyl group. In one embodiment, the organic ammonium cation may be phenethylammonium.

The term “ring” refers to any covalently closed structure. Rings include, for example, carbocycles (e.g., aryls and alicyclics), heterocycles (e.g., heteroaryls and non-aromatic heterocycles), aromatics (e.g., aryls and heteroaryls), and non-aromatics (e.g., alicyclics and non-aromatic heterocycles). Rings may be optionally substituted.

In various embodiments, in formula (I), X1, X2, X3, and X4 are the same, or in formula (II), X1, X2, X3, X4, X5, and X6 are the same, or in formula (III), X1, X2, and X3 are the same. In other words, the Cu-perovskite material of formula (I) can be (A1)ₐ(A2)_{b}CuCl₄, (A1)ₐ(A2)_{b}CuBr₄, (A1)ₐ(A2)_{b}Cul₄, or (A1)ₐ(A2)_{b}CuF₄. Similarly, the Cu- perovskite material of formula (II) can be (A1)ₐ(A2)_{b}CuCl₆, (A1)ₐ(A2)_{b}CuBr₆, (A1)ₐ(A2)_{b}CuI₆, or (A1)ₐ(A2)_{b}CuF₆. Likewise, the Cu-perovskite material of formula (III) can be (A1)ₐCuCl₃.

In alternative embodiments, in formula (I), at least one of X1, X2, X3, and X4 is different from the rest, or in formula (II), at least one of X1, X2, X3, X4, X5, and X6 is different from the rest, or in formula (III), at least one of X1, X2, and X3 is different from the rest. In other words, the Cu-perovskite material of formula (I) can be (A1)ₐ(A2)_{b}CuCl_{0.5}Br_{3.5}, (A1)ₐ(A2)_{b}CuClBr₃, (A1)ₐ(A2)_{b}CuCl_{1.5}Br_{2.5}, (A1)ₐ(A2)_{b}CuCl₂Br₂, (A1)ₐ(A2)_{b}CuCl_{2.5}Br_{1.5}, (A1)ₐ(A2)_{b}CuCl₃Br, or (A1)ₐ(A2)_{b}CuCl_{3.5}Br_{0.5}. Similarly, the Cu-perovskite material of formula (II) can be (A1)ₐ(A2)_{b}CuCl_{0.5}Br_{5.5}, (A1)ₐ(A2)_{b}CuClBr₅, (A1)ₐ(A2)_{b}CuCl_{1.5}Br_{4.5}, (A1)ₐ(A2)_{b}CuCl₂Br₄, (A1)ₐ(A2)_{b}CuCl_{2.5}Br_{3.5}, (A1)ₐ(A2)_{b}CuCl₃Br₃, (A1)ₐ(A2)_{b}CuCl_{3.5}Br_{2.5}, (A1)ₐ(A2)_{b}CuCl₄Br₂, (A1)ₐ(A2)_{b}CuCl_{4.5}Br_{1.5}, (A1)ₐ(A2)_{b}CuCl₅Br, or (A1)ₐ(A2)_{b}CuCl_{5.5}Br_{0.5}.

Conveniently but not necessarily so, in formula (I) or (II) of the Cu-perovskite material, A1 and A2 are the same. For example, in formula (I) or (II), A1 and A2 are CH₃NH₃⁺.

In other embodiments, in formula (I) or (II) of the Cu-perovskite material, A1 and A2 are different. As an example, in formula (I) or (II), A1 is CH₃NH₃⁺ and A2 is C₂H₅NH₃⁺.

Further tuning of optoelectrical properties can be achieved by chemical doping using mixed metal hybrid perovskites such as the system (CH₃NH₃)₂CuₓMn₁₋ₓX₄ or any other combination of transition metals in the +2 oxidation state (e.g. chromium (Cr), manganese (Mn), iron (Fe), cobalt (Co), nickel (Ni), zinc (Zn), palladium (Pd), cadmium (Cd), mercury (Hg)).

Accordingly, in various embodiments, in formula (I), Cu can be doped with a transition metal in the +2 oxidation state. In formula (II), Cu can be doped with a transition metal in the +4 oxidation state so as to improve the optoelectronic properties thereof.

The copper-based perovskite acting as a light harvester require its implementation with the proper semiconductor or metal contacts for the photovoltaic generation.

Thus, in accordance with another aspect, an optoelectronic device is described herein. The optoelectronic device comprises:
an active layer comprising a copper-based perovskite material according to the earlier aspect, wherein the active layer is arranged in between a charge carrier transporting layer and a charge carrier blocking layer;
a conducting substrate; and
a current collector.

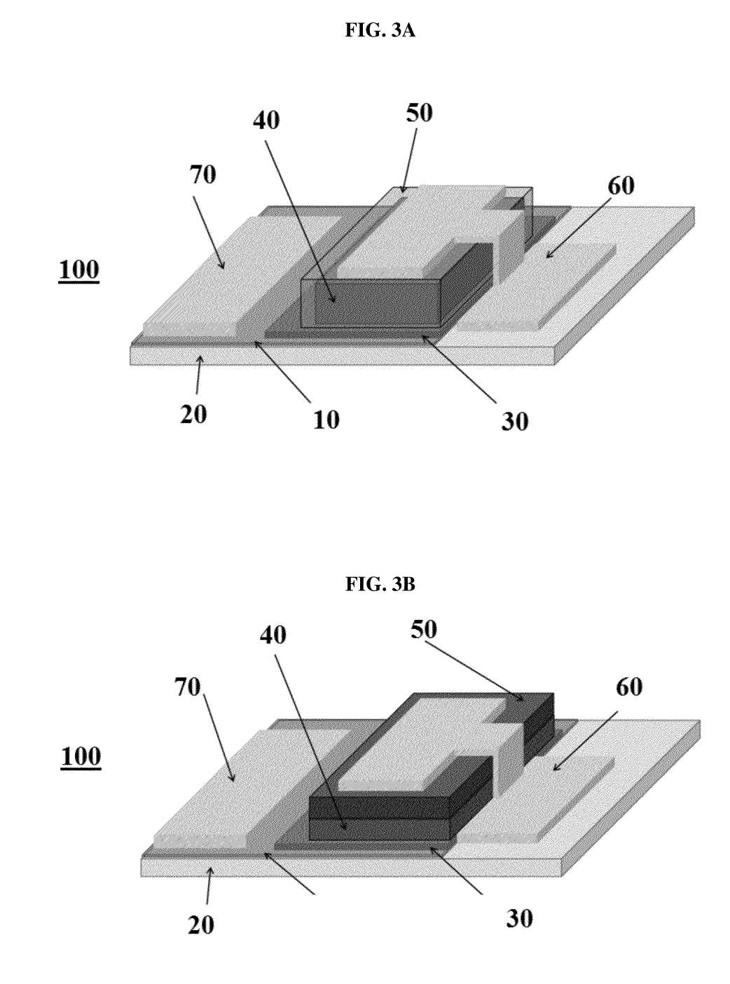

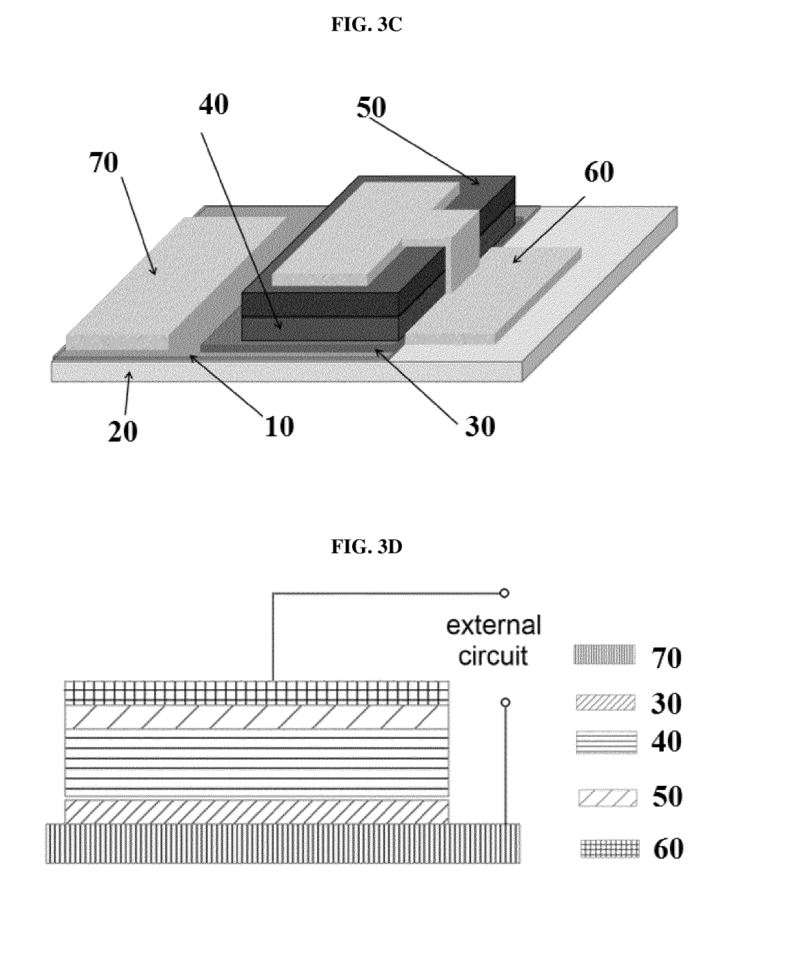

A scheme of the device architecture in various configuration is represented in FIG. 3A-D.

In one embodiment, the active layer comprises a thin film of the copper-based perovskite material. In other words, the Cu-perovskite is able to form the light harvesting layer by itself, i.e. in a thin film configuration or in a bulk-heterojunction configuration.

In an alternative embodiment, the active layer comprises the copper-based perovskite material comprised in the pores of a mesoporous semiconductor layer.

In various embodiments, the active layer can be arranged in between an electron transporting layer and an electron blocking layer. The electron selective contact can be formed by inorganic or organic materials such as titanium dioxide (TiO₂), fullerene-based materials (such as Phenyl C61 butyric acid methyl ester (PCBM)), tin oxide (SnO₂) and others, which conduction band allows the electron injection from the Cu-based perovskite.

In other embodiments, the active layer can be arranged in between a hole transporting layer and a hole blocking layer. The hole selective contact can consist of solid organic and inorganic materials such as 2,2′,7,7′-tetrakis(N,N′-di-p-methoxyphenylamine)-9,9′-spirobifluorene (spiro-OMeTAD), thiophene derivatives, copper thiocyanate and others, or liquid electrolytes, which energetics allow the hole injection from the Cu-based perovskite.

An inverted structure of the optoelectronic device is also feasible. In this case the Cu-perovskite is deposited on a mesoporous p-type material and sandwiched between a p-type semi-transparent compact layer (e.g. nickel (II) oxide (NiO), copper (II) oxide (CuO)) and an electron transporting material (e.g. PCBM, zinc oxide (ZnO)) which accepts electrons from the photoexcited perovskite. The photogenerated holes are extracted through the valence band of the p-type semiconductor.

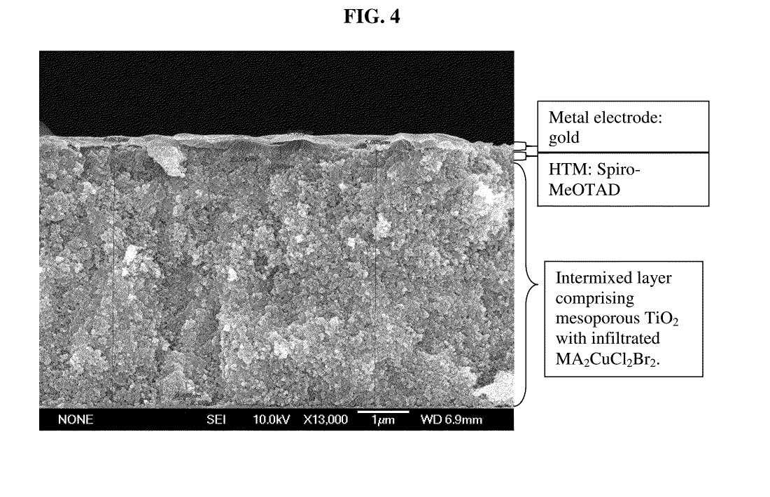

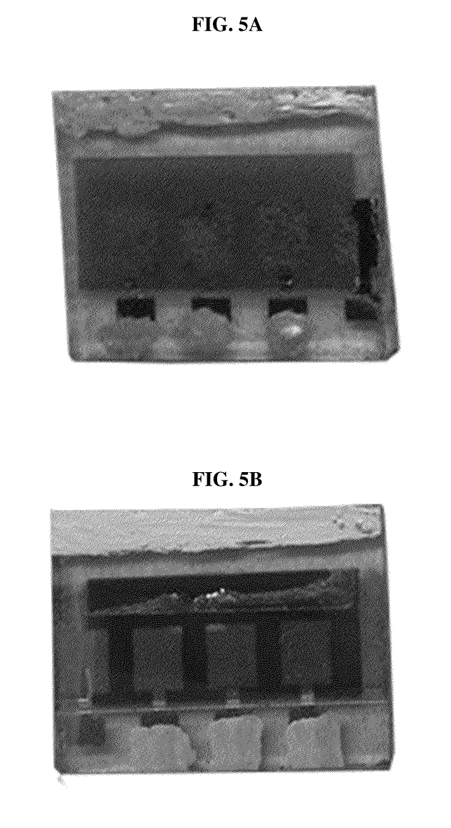

An example of the cross section of a device with structure “compact TiO₂/mesoporous TiO₂/(CH₃NH₃)₂CuCl₂Br₂ perovskite/spiro-OMeTAD/gold” and pictures of solar cells based on mesoporous titania sensitized with (CH₃NH₃)₂CuCl₂Br₂ and (CH₃NH₃)₂CuCl_{0.5}Br_{3.5} are shown, respectively, in FIG. 4 and FIG. 5A-B.

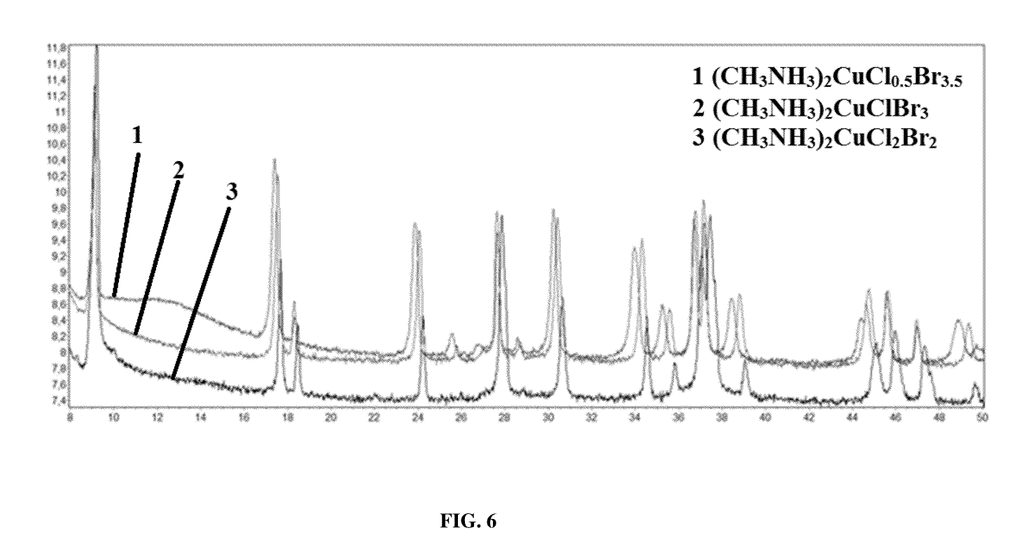

The deposition of perovskite by means of physical (such as evaporation, epitaxial growth or others) or chemical (from solution, single crystals or others) techniques can be done onto planar contacts (forming a film) or infiltrated on mesoscopic ones. From solution, the perovskite can be processed dissolving the previously synthesized perovskite powder or from a precursor solution. In the first case, the perovskite can be first crystallized from solution (e.g. methanol, ethanol, 2-propanol), and an example of powder XRD of Cu-perovskites with different Cl/Br ratio obtained through this method is given in FIG. 6. In this case, the shift of the diffraction peaks towards smaller angles increasing the relative amount of Br is due to the increased dimensions of the unit cell. The powders can be further dissolved in a suitable solvent for the spin coating (e.g. DMSO, GBL, DMF) and deposited in thin films or infiltrated in porous structures. In an alternative embodiment, the inorganic and organic precursors, like methylammonium iodide and copper (II) bromide, can be dissolved and the solution directly used for the deposition.

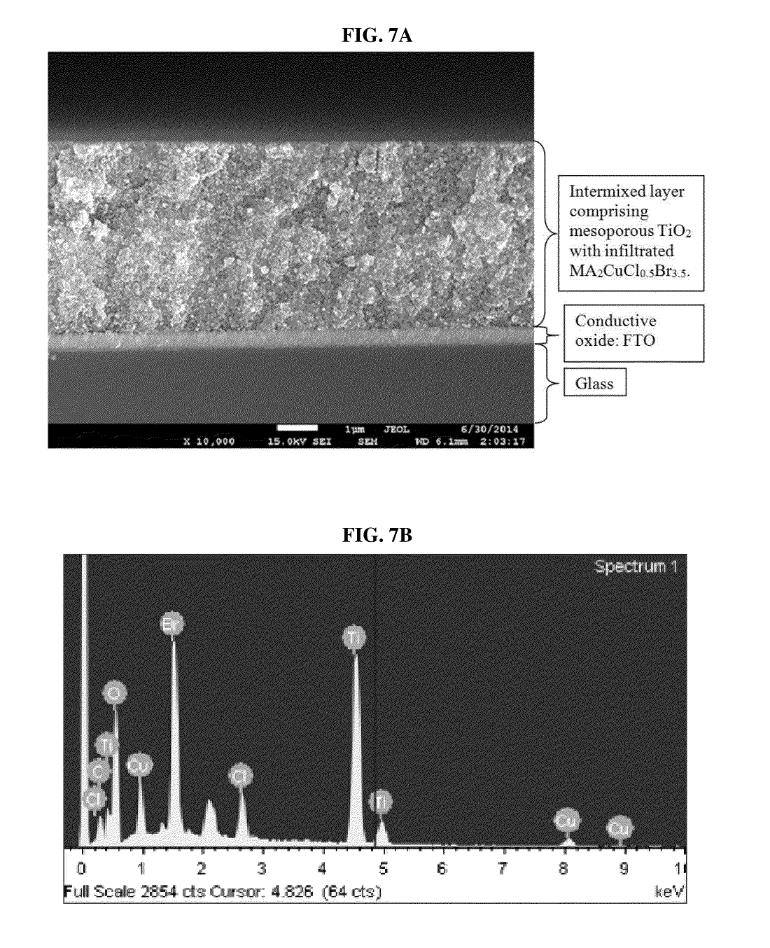

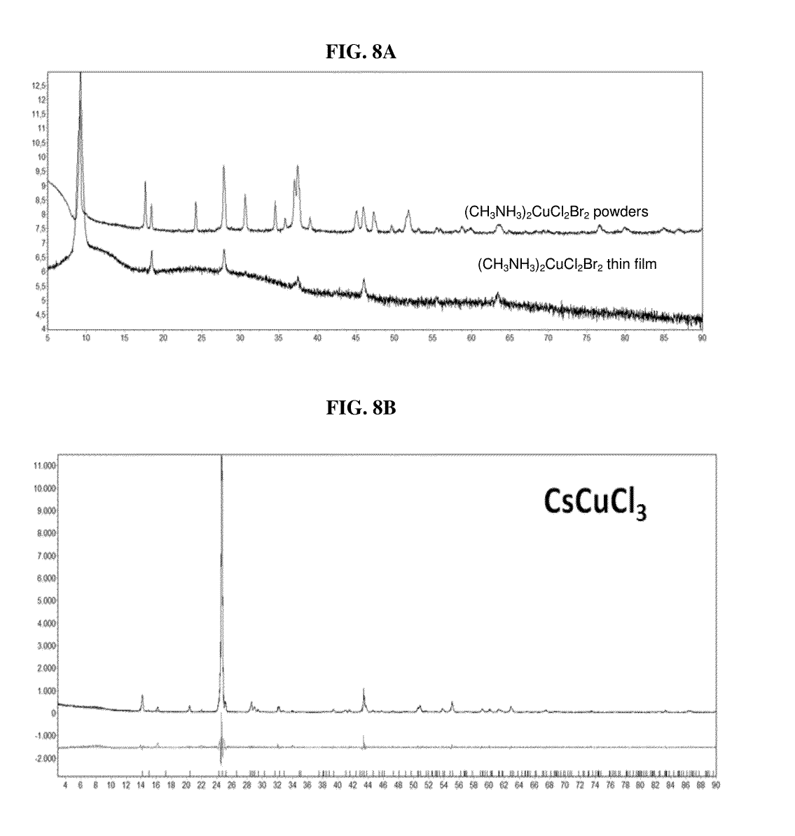

A cross section example of a mesoporous TiO₂ infiltrated with the perovskite (CH₃NH₃)₂CuCl_{0.5}Br_{3.5} and its respective EDX spectrum is shown in FIG. 7A-B. A typical XRD diffractogram of a (CH₃NH₃)₂CuCl₂Br₂ thin film deposited by spin coating on glass is shown in FIG. 8A and compared to the diffractogram of the powder. Only selected reflections are visible in the thin film due to the strong preferential orientation towards the 001 direction. FIG. 8B shows an example of thin film XRD pattern of CsCuCl₃.

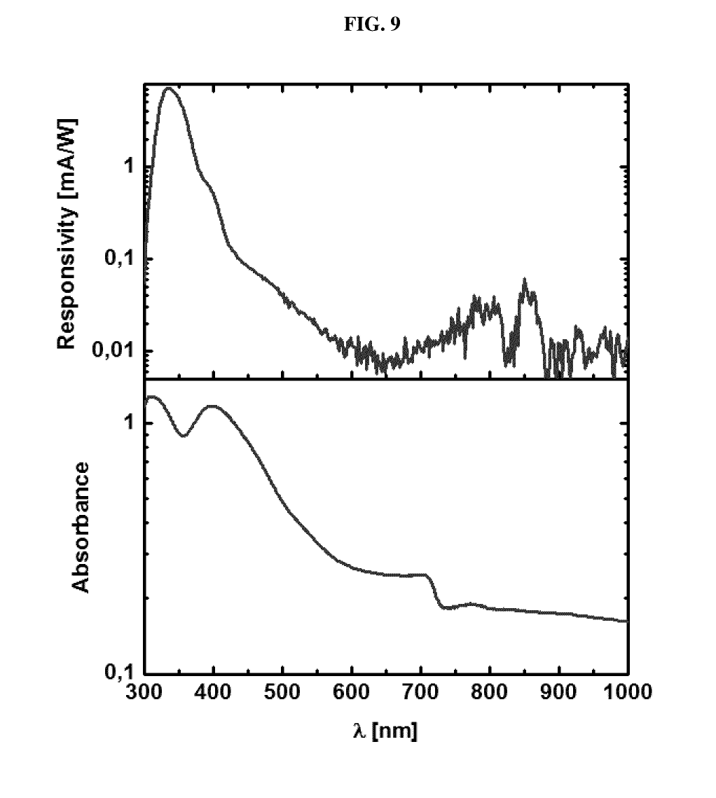

The photogeneration of the perovskite is confirmed with photocurrent measurements performed on a solar cell based on mesoporous TiO₂ infiltrated with (CH₃NH₃)₂CuCl₂Br₂. The results clearly show the sensitization of the titania by the perovskite, as shown in FIG. 9, where the generated photocurrent matches the absorption spectrum of the perovskite sensitizer.

In order that the invention may be readily understood and put into practical effect, particular embodiments will now be described by way of the following non-limiting examples.

### EXAMPLES

### Example 1

In this example, fabrication of a photovoltaic device 100 based on Cu-perovskite is described in the following paragraphs.

Synthesis of Cu-perovskite: (CH₃NH₃)₂CuBr₂Cl₂ is synthesized by dissolving CH₃NH₃C1 (1.94 g, 28.8 mmol) and CuBr₂ (2.67 g, 12 mmol) in 100 ml of ethanol solvent. The solution is stirred at 60° C. for 30 minutes, then the perovskite is crystallized by leaving the solution in an ice-bath overnight, collected by filtration and dried at 60° C. for 12 h in a vacuum oven. The reaction can be written as:

2CH₃NH₃Cl+CuBr₂→(CH₃NH₃)₂CuCl₂Br₂

Fabrication of the photovoltaic device 100: An indium tin oxide (ITO) coating 10 either on a plastic substrate (such as polyethylene naphthalate (PEN), polyethylene terephthalate (PET), etc) or a glass substrate 20 acts as a transparent conductive contact 70. The deposition of a compact layer of titanium dioxide (TiO₂) 30 (by electro deposition or spin coating or atomic layer deposition) reduces the recombination with the contact and creates a base for the perovskite absorber deposition. An extra nanostructured TiO₂ layer can be spin coated or screen printed to form a mesoporous structure 40 in order to increase the amount of perovskite absorber loading. This substrate acts as an electron collector.

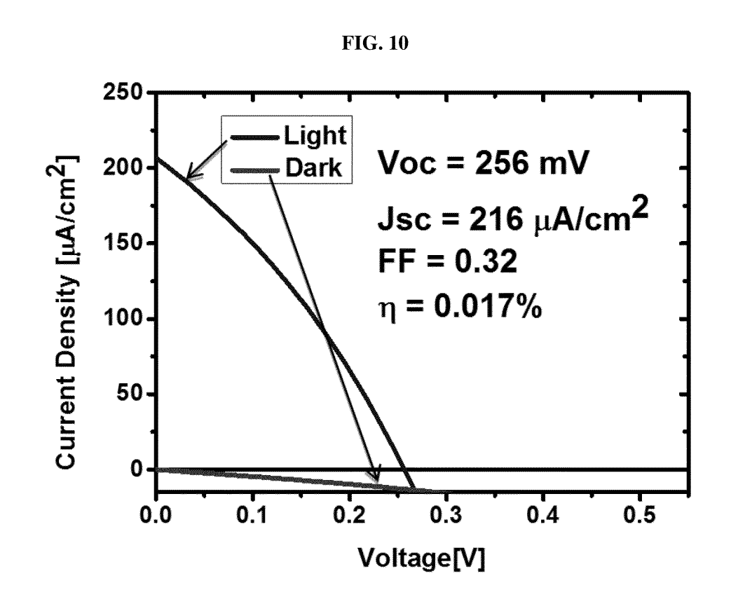

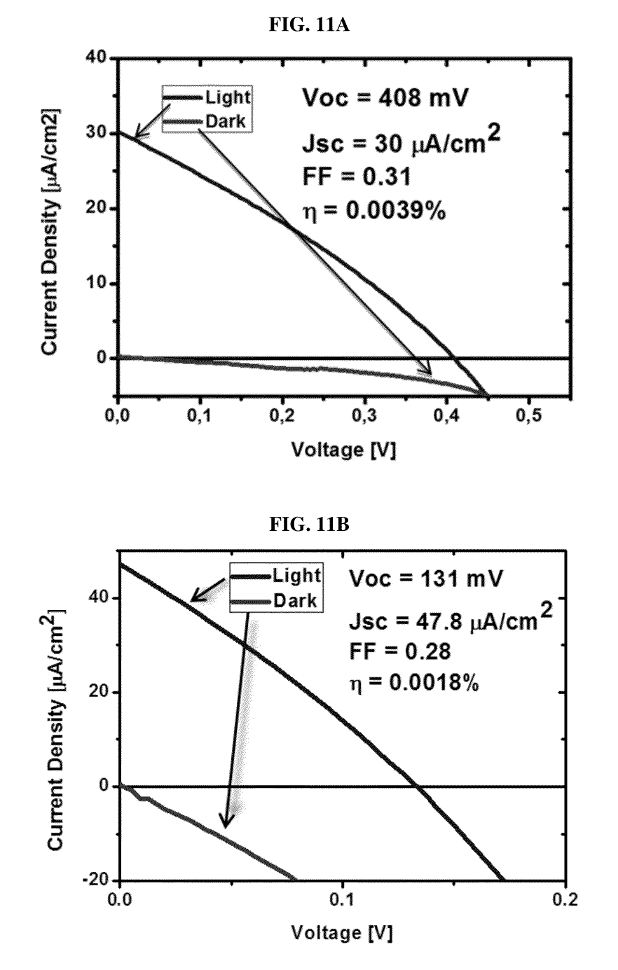

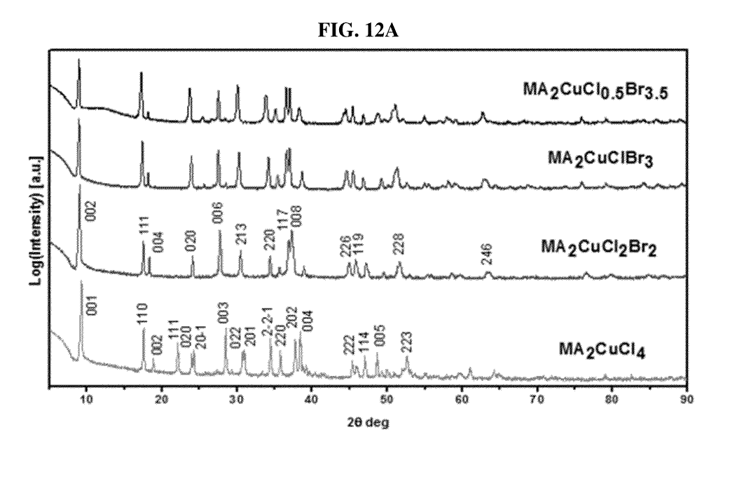

The deposition of the perovskite absorber can be made from a solution of 90 mg of Cu-perovskite in 250 μL of dimethyl sulfoxide (DMSO). A thin film of the Cu-perovskite is spin coated onto the TiO₂ substrate from the heated solution (70° C.) and annealed at 70° C. for 1 h. To complete the fabrication of the device, a hole collector material 50 (in this case, 86.4 mg of spiro-OMeTAD) is deposited by spin coating from a solution in 480 μL of toluene solvent. With this configuration, after gold has been deposited as a metal contact 60, a photovoltaic power conversion efficiency of 0.017% can be achieved (FIG. 10). An example with similar device architecture and (CH₃NH₃)₂CuBr₄ acting as a light harvesting material is shown in FIG. 11A, with a power conversion efficiency of 0.0039%. Another example relative to a mesoporous solar cell (300 nm of mesoporous TiO₂) sensitized with CsCuCl₃ reaching power conversion efficiency of 0.0018% is shown in FIG. 11B. In the latter case, CsCuCl₃ was obtained by direct spin coating of 0.5M DMSO solutions of its precursors (CsCl and CuCl₂) in 1:1 molar ratio, followed by annealing at 100° C. for 10 minutes.

### Example 2

In this example, the series (CH₃NH₃)₂CuCl₄₋ₓBrₓ was studied in detail, where the role of Cl is found to be essential for the stabilization against Cu²⁺ reduction. The optical properties of these compounds can be effectively tuned by changing the Br/Cl ratio, which affects metal-to-ligand charge transfer transitions, and by exploiting additional Cu d-d transitions, overall extending the optical absorption down to the near-infrared for optimal spectral overlap with the solar irradiance. Processing conditions for integrating Cu-perovskite into photovoltaic device architectures as well as factors currently limiting photovoltaic performance are discussed: these include electron trapping induced by partial Cu reduction and morphological effects on charge extraction. This example clearly demonstrates the potential of 2D copper perovskite light harvesters to replace harmful Pb-perovskites.

The synthesis and characterization of a 2D copper-based hybrid perovskite family with the general formula (CH₃NH₃)₂CuCl₄₋ₓBrₓ is discussed hereinafter. As mentioned, the presence of Cl⁻ is essential to improve the material stability against copper reduction and enhance the perovskite crystallization. By changing the Br/Cl ratio, the optical absorption can be tuned within the visible to near-infrared (λ=300-900 nm) range. Optical transitions of this new class of materials were understood and assigned using ab-initio calculations based on the density functional theory (DFT). Thin film fabrication and deposition parameters were also studied to optimize integration of these materials into a photovoltaic device structure. The solar cell performance and the factors currently limiting the efficiency of this device are discussed to provide guidelines for future optimization and investigation of lead-free perovskite.

### Experimental Method

### Synthesis of MA₂CuClₓBr₄₋ₓ Perovskite Powders

Methylammonium chloride (CH₃NH₃C1 or MACl for short) and methylammonium bromide (CH₃NH₃Br or MABr for short) were synthesized by mixing 16.7 ml and 18.0 ml of methylamine solution (CH₃NH₂, 40% in methanol) with 11.3 ml of hydrochloric acid (HCl) (37% wt in water) and 8.0 ml of hydrobromic acid HBr (48% in water, Sigma-Aldrich), respectively. The white powders obtained were purified by crystallization from ethanol (EtOH) with diethyleter and dried in vacuum oven (12 h, 60° C.).

Perovskite powders (CH₃NH₃)₂CuCl₄, (CH₃NH₃)₂CuCl₂Br₂, (CH₃NH₃)₂CuClBr₃ and (CH₃NH₃)₂CuCl_{0.5}Br_{3.5} were synthesized from ethanol solutions. The precursors MACl, MABr, CuCl₂ (copper chloride, 99% Sigma-Aldrich), CuBr₂ (copper bromide, 99% Sigma-Aldrich) were mixed in the desired stoichiometry (1.2 equivalents of organic precursors were used to ensure the complete reaction of the inorganic salts). For example, to obtain (CH₃NH₃)₂CuCl_{0.5}Br_{3.5}, 2.68 g of CuBr₂, 2.42 g of CH₃NH₃Br and 0.48 g of CH₃NH₃C1 were mixed in 100 ml of EtOH, stirred for 2 h at 60° C. and left to crystallize overnight in an ice bath. The product was recovered by filtration, dried at 60° C. for 12 h in vacuum oven and stored in glove-box.

Material Characterization

BRUKER D8 ADVANCE with Bragg-Brentano geometry was used for X-ray analysis, with Cu Kα radiation (1=1.54056 Å), step increment of 0.02° and is of acquisition time. An air sensitive sample holder was used for thin film characterization. The software TOPAS 3.0 was used for XRD data analysis. In the case of (CH₃NH₃)₂CuCl₄ and (CH₃N₃)₂CuCl₂Br₂, structural data reported in ICSD #110687 and ICSD #110677 were used to perform the Rietweld refinement. The Pawley fitting for (CH₃NH₃)₂CuClBr₃ and (CH₃NH₃)₂CuCl_{0.5}Br_{3.5} was done starting from the lattice parameters and crystal structure of (CH₃NH₃)₂CuCl₂Br₂. The data fitting was done using the fundamental parameters approach. Peak profile and background were fit respectively with a TCHZ Pseudo-Voigt function and a Chebichev polynomial of fifth order with 1/x function. The refined parameters were the zero error, scale factor, linear absorption coefficient and lattice parameters. Diamond 3.2 software was used to draw the crystal structure.

X-ray photoelectron spectroscopy (XPS) measurements were done using monochromatic X-ray source from Al Kₐ (hv=1486.7 eV) and a hemispherical analyzer (EA125, Omicron). The Ultraviolet photoelectron spectroscopy (UPS) is measured using the sample analyzer but with a UV source from a helium discharge lamp (hv=21.2 eV). To eliminate air induced change to Cu-perovskite samples, a direct transfer method (direct transfer from glove box to vacuum condition) is used to avoid air contact during sample transfer.

Morphological and compositional characterization was done with a field emission scanning electron microscope (FE-SEM) coupled with an energy dispersive X-ray analysis (EDX) Jeol JSM-6700F.

The instrument 2950 TGA HR V5.4 (TA Instruments) was used for the thermogravimetric analysis. The analysis was performed under nitrogen (flow rate 40 ml/min) and an interval from 30° C. to 900° C. (ramp rate 5° C./min) was studied.

A UV-Vis-Nir Spectrophotometer (UV3600, Shimadzu) was used for optical characterization. Absorption spectra were measured on perovskite thin films deposited by spin coating on glass slides from DMSO solutions of the perovskite powders and protected against moisture with poly(methyl methacrylate) (PMMA) layers. In order to calculate the absorption coefficients, the thickness of the film was measured with the surface profiler Alpha-Step IQ.

Computational Methods

All the structural optimization and electronic structure calculations were performed by the QUANTUM ESPRESSO code in the framework of density functional theory (DFT). The general gradient approximation (GGA) functional of Perdew-Burke-Ernzerhof (PBE) was employed. Electron-ion interactions were described by ultrasoft pseudopotentials with electrons from H (1s); 0, N and C (2s, 2p); Cl (3s, 3p); Br (4s, 4p); Cu (3s, 3p, 3d, 4s, 4p), shells explicitly included in the calculations. Single-particle wave functions (charges) were expanded on a plane-wave basis set up to a kinetic energy cutoff of 50 Ry (300 Ry) and k-point mesh of 4*4*4 for MA₂CuCl₄ and 4*4*2 for MA₂CuCl₂Br₂, MA₂CuClBr₃, MA₂CuCl_{0.5}Br_{3.5} were chosen here considering accurate and computational point. The experimental crystal structures of monoclinic or orthorhombic coordinates at room temperature were used as an initial guess. The atomic relaxation calculations were performed by fixing the Cu atoms and allowing other atoms to relax until the residual atomic forces are less than 0.002 eV/A. The approach to the DFT+U method introduced by Dudarev et al. was used in all calculations to include the strongly correlated effects on the d states of Cu, and the on-site Coulomb interaction parameter (U=7.5 eV) was adopted in the calculations.

Solar Cell Fabrication

Direct Structure: Fluorine doped tin oxide (FTO) glass substrates were cleaned with sonication in decon soap, deionized H₂O and ethanol each for 30 min. Spray pyrolysis was used to deposit the compact TiO₂ blocking layer using a precursor solution of titanium diisopropoxide bis(acetylacetonate), then the substrate were treated with 0.1M TiCl₄ solution at 70° C. for 1 h. Mesoporous TiO₂ layers (5 μm) were screen printed using the paste DSL30NRD (Dyesol) and sintered at 500° C. 1M DMSO solutions were prepared by dissolving the preformed perovskite powders and spin coated with the following parameters: 500 rpm, 30 s—1000 rpm, 30 s—4000 rpm, 180 s. The annealing was done on a hotplate at 70° C. for 1 h. Spiro-MeOTAD was spin coated from chlorobenzene solution (180 mg/ml) at 4000 rpm for 30 s. No additives to the hole transporter layer were employed during this study. Gold electrodes were deposited by thermal evaporation, defining an active area of the solar cell of 0.2 cm². Perovskite, spiro-MeOTAD and gold deposition were performed in glove-box.

Inverted structure: ITO substrates were etched using zinc powder and diluted HCl, cleaned and exposed to oxygen plasma for 2 min. Poly(3,4-ethylenedioxythiophene):polystyrene sulfonate (PEDOT:PSS) was deposited from water solution at 3000 rpm, 60 s and annealed on hotplate (125° C., 20 min). Under N₂ atmosphere, 1M DMSO solution of (CH₃NH₃)₂CuCl₂Br₂ was then spin coated with steps 500 rpm, 30 s—1000 rpm, 30 s—4000 and the film was annealed at 70° C. for 1 h. Phenyl C61 butyric acid methyl ester (PCBM) was spin coated from 20 mg/ml chloroform/chlorobenzene 1:1 solutions at 1000 rpm for 50 s, and aluminum electrodes were finally deposited defining an active area of 0.07 cm².

Solar Cell Characterization

The current voltage characteristics were measured using an Agilent 4155C analyzer and under AM 1.5G simulated illumination from a solar simulator (San-EI Electric, XEC-301S).

Photocurrent Measurements

The responsivity was calculated according to the equation Rᵢ=iₚₕ/Pᵢₙ where Pᵢₙ is the light power incident onto the surface of the sample and iₚₕ is the measured photocurrent. The responsivity was measured with conventional amplitude modulation technique using a Xe lamp as white light source and a monochromator to disperse the light within the range of 300 to 900 nm. The modulation was done using a mechanical chopper at frequency of 138 Hz and the monochromatic light intensity was determined by a calibrated reference photodiode. Time constant of the lock-in amplifier was set to 300 ms, which corresponds to 0.42 Hz equivalent noise bandwidth.

Impedance Spectroscopy

The measurements were performed inside a N₂ filled glove box with an Autolab PGSTAT128N. Under 1 sun illumination, a 20 mV perturbation was applied with frequencies varying from 200 kHz to 1 Hz and DC voltages from 0 to 300 mV.

XRD Study with Increasing Br/Cl Ratio

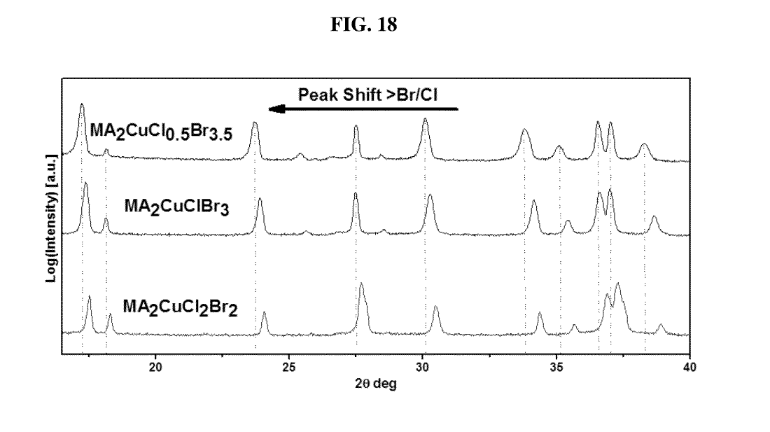

Due to the bigger ionic radius of Br compared to Cl, the increase in Br/Cl ratio augments the unit cell dimensions, resulting in progressive peak shift to lower diffraction angles with Br addition from MA₂CuCl₄ to MA₂CuCl_{0.5}Br_{3.5} (FIG. 18).

Thermogravimetric Analysis (TGA)

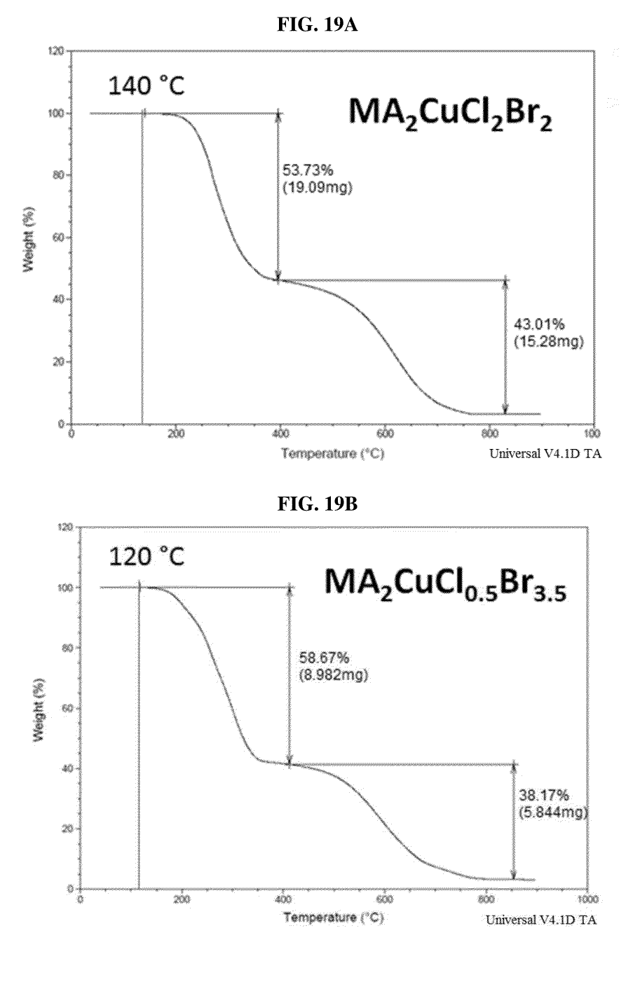

TGA of MA₂CuCl₂Br₂ to MA₂CuCl_{0.5}Br_{3.5} is shown in FIG. 19A and FIG. 19B, respectively. The decomposition profile proceeds with two steps, and the first weight loss increases with higher Br content, indicating a major loss of Br compounds during this step, such as MABr and HBr, together with the release of MACl and HCl and CH₃NH₂. At higher temperatures, the decomposition is possibly accompanied with the formation of higher boiling point compounds such as CuCl₂.

Annealing Study

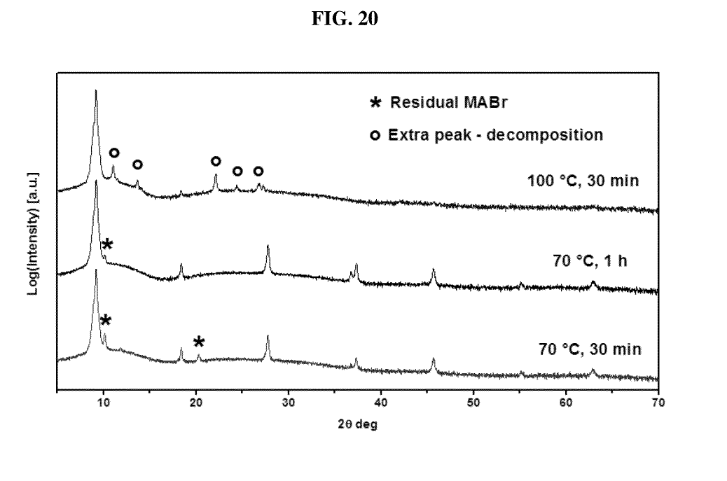

Annealing of MA₂CuCl_{0.5}Br_{3.5} films (FIG. 20) at 100° C. results in the loss of peaks characteristic of perovskites, and extra peaks appear between 10° and 30°. Samples annealed at 70° C. for 30 min display residual MABr which is minimized with prolonged annealing at 70° C. for 1 h.

Band Gap Determination

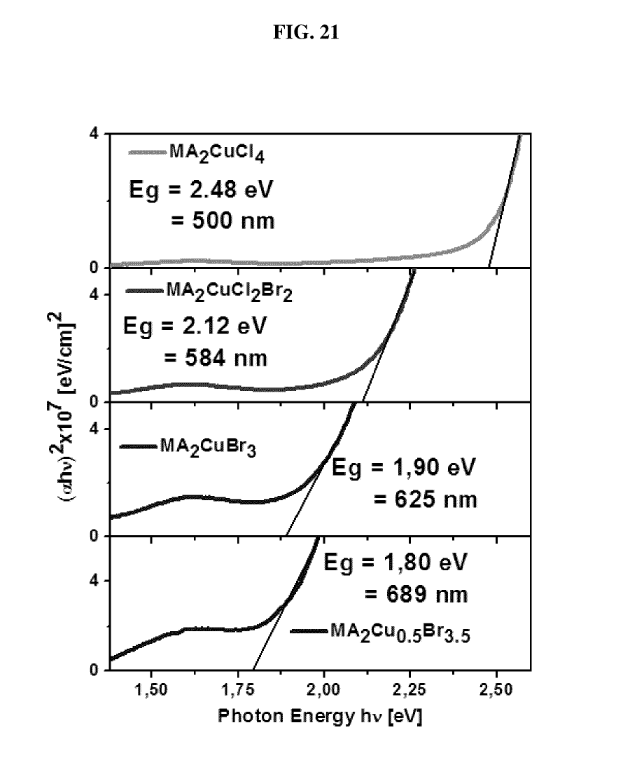

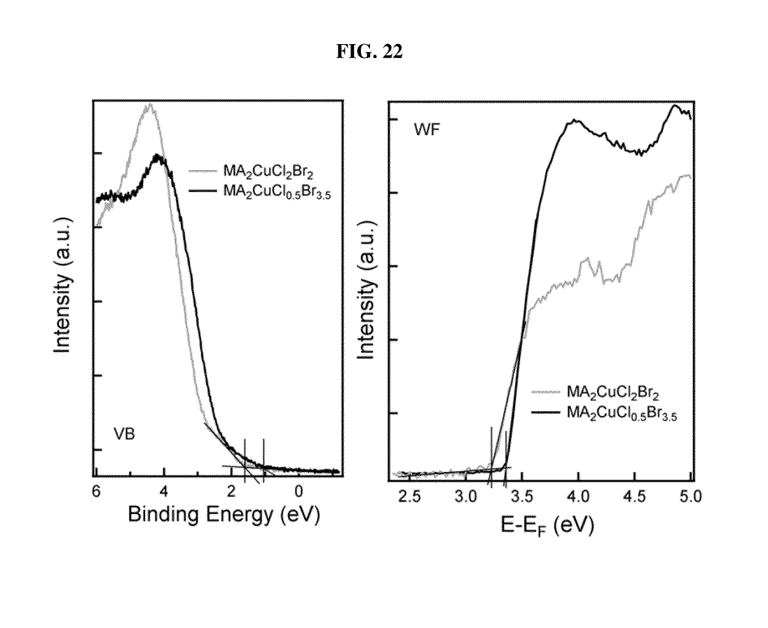

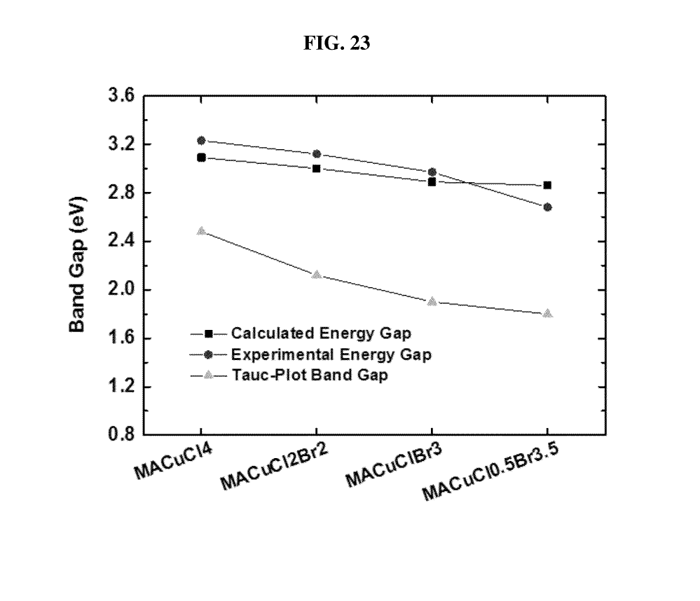

Tauc Plot construction for the determination of perovskite's direct band gap associated to CT transitions (FIG. 21).

Binding Energy and Work Function Determination

Binding energy (BE) and work function (WF) determination for MA₂CuCl₂Br₂ and MA₂CuCl_{0.5}Br_{3.5} by ultraviolet photoelectron spectroscopy (UPS) (FIG. 22).

Comparison Between Experimentally Derived and Simulated Band Gaps

Comparison between experimental and simulated data (FIG. 23). The calculated excitonic band gap matches with the value of the CT transition determined from absorption spectra. Both experimental results and simulated data indicate the same trend in terms of decreasing band-gaps with increasing Br/Cl ratio.

Density of States Based on DFT Calculations

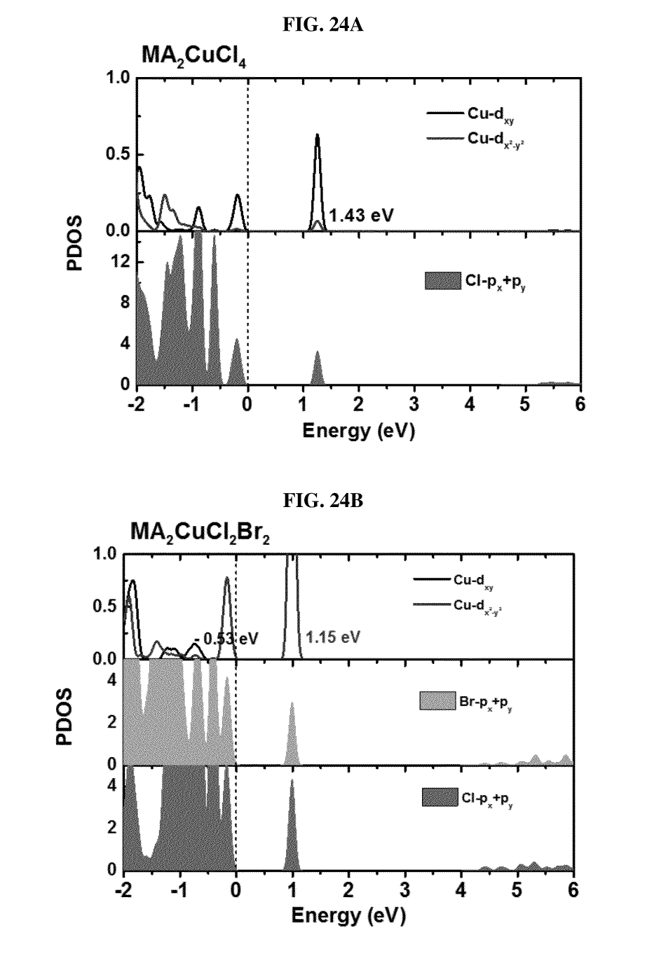

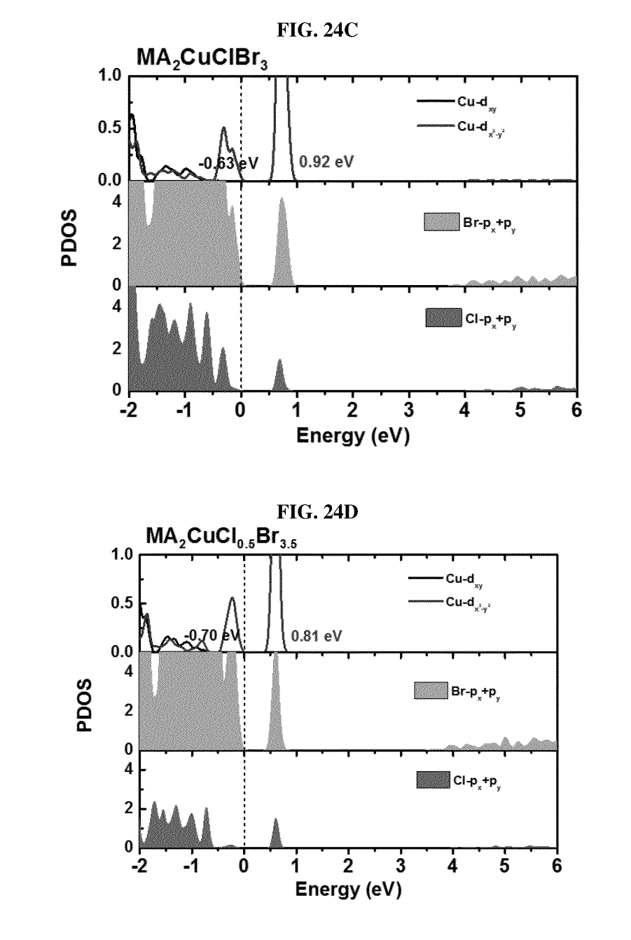

Projected density of states of the four copper pervoskite compounds (a) MA₂CuCl₄, (b) MA₂CuCl₂Br₂, (c) MA₂CuClBr₃, and (d) MA₂CuCl_{0.5}Br_{3.5} from DFT calculations (FIG. 24A-D).

SEM Images of Infiltration of TiO2 with the Cu Perovskite

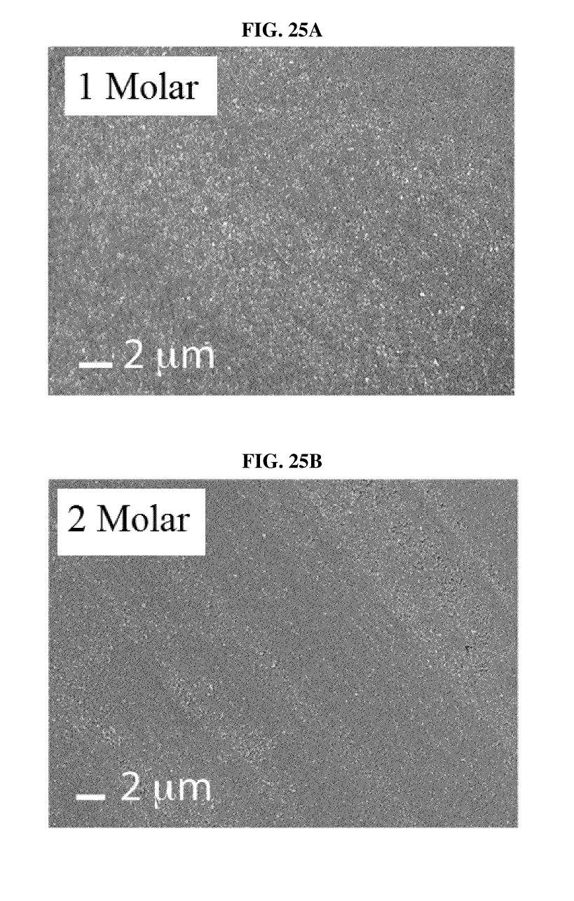

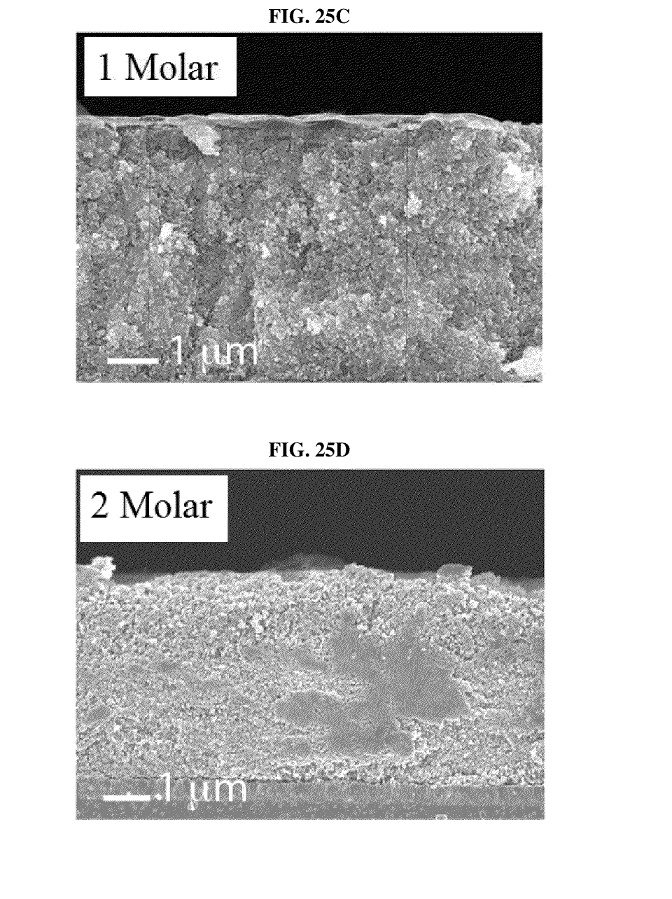

SEM images of mesoporous TiO2 infiltrated with MA₂CuCl₂Br₂ using DMSO solution of different concentration: 1M (FIG. 25A, FIG. 25C) and 2M (FIG. 25B, FIG. 25D).

Inverted Solar Cell

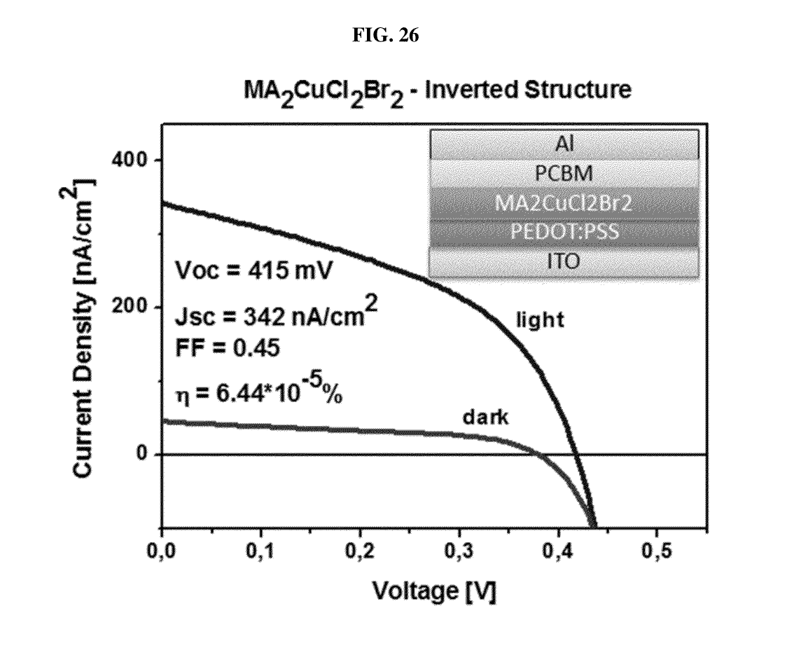

Copper perovskite-based solar cell with inverted structure PEDOT:PS S/MA₂CuCl₂Br₂/PCBM (FIG. 26).

X-Ray Photoelectron Spectroscopy (XPS)

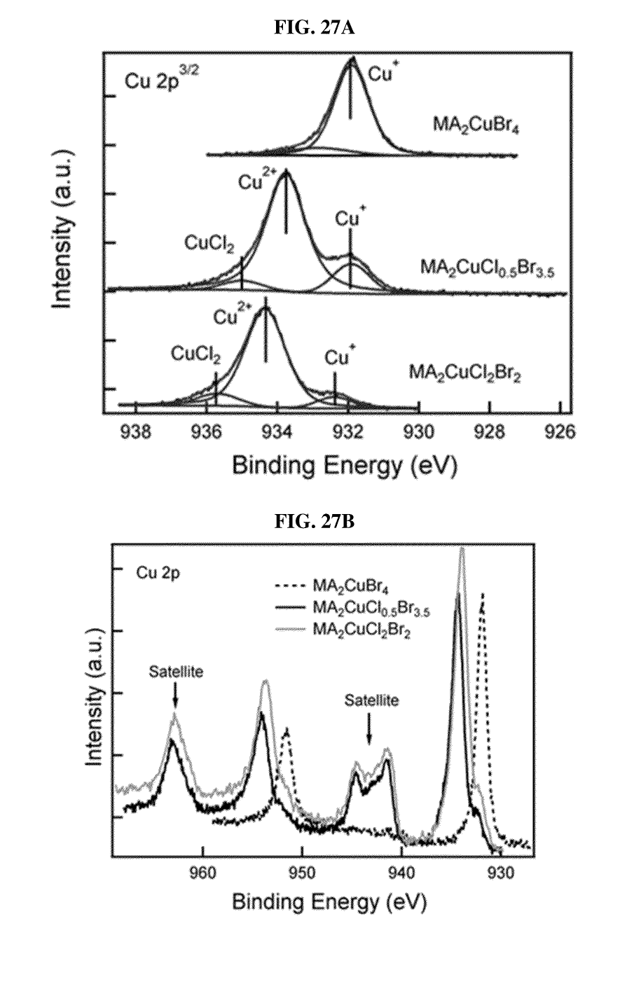

XPS analysis of MA₂CuCl₂Br₂ and MA₂CuCl_{0.5}Br_{3.5} (FIG. 27A-B). In Cu 2p spectra, samples with chlorine show satellite peaks, indicating the presence of Cu²⁺ ions. In pure bromine sample, no satellite peak suggest the surface of this sample changes to Cu⁺.

Impedance Analysis of the Cu Perovskite

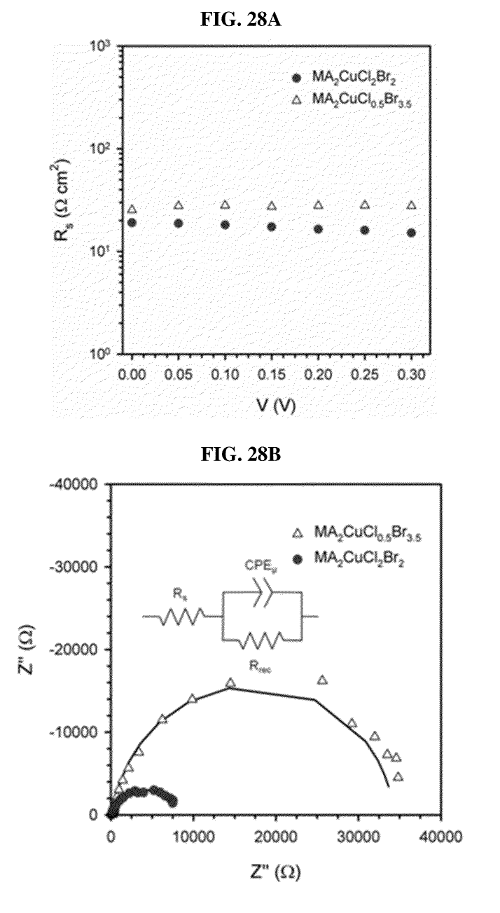

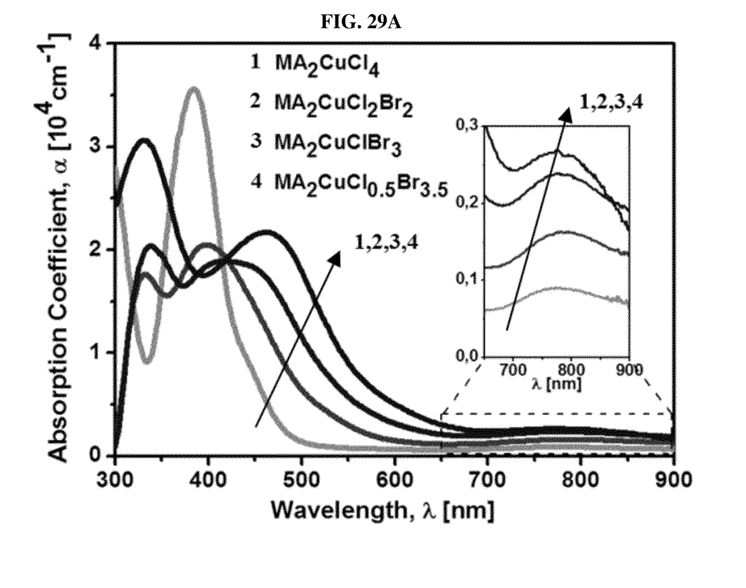

FIG. 28A shows series resistance extracted from the fitting of the impedance spectrum measured under 1 sun; and FIG. 28B shows example of impedance spectra under 1 sun at 0.25 V for both analyzed samples, the inset represents the equivalent circuit employed for the fitting.

Results and Discussion

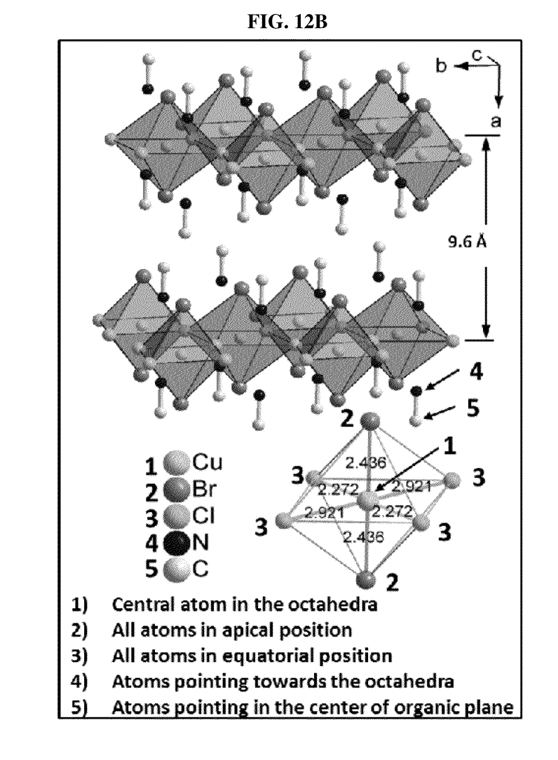

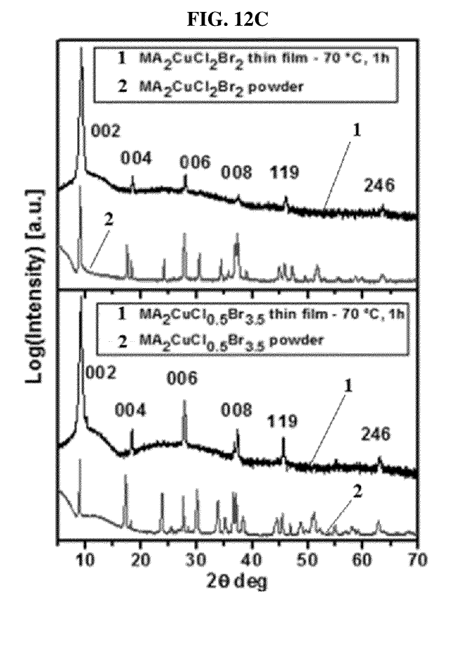

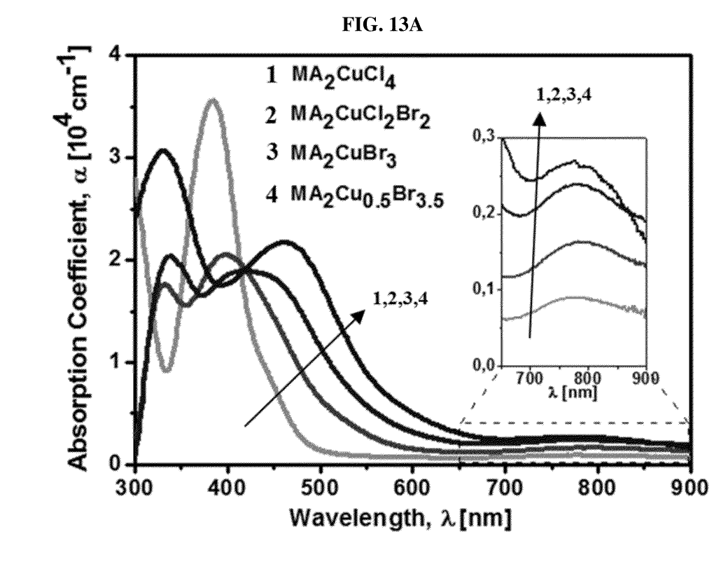

The fundamental properties of MA₂CuClₓBr₄₋ₓ, were first studied by synthesizing powders with different Br/Cl ratio. The perovskite crystallized spontaneously from alcohol solution, however higher bromine content increased the instability of the material. Attempts to synthesize a fully bromine-substituted compound were not successful, and the presence of chlorine was found to be essential to allow crystallization and improve materials stability against Cu²⁺ reduction caused by bromine. The material obtained with the highest Br/Cl ratio was MA₂CuCl_{0.5}Br_{3.5}. FIG. 12A displays the diffractograms of all the powders synthesized and Table 1 summarizes their crystallographic properties.

TABLE 1
Crystal structure and lattice parameters of Cu-based perovskites. R_{wp} = {Σᵢ wᵢ[yᵢ(obs) −
yᵢ(calc)]²/Σᵢ wᵢ[yᵢ(obs)]²}^{1/2}, where yᵢ(obs) and yᵢ(calc) are the observed and calculated
intensities at the step i, respectively, and wᵢ is the weight.

| | Crystal | Space | | | | | |
|---|---|---|---|---|---|---|---|
| Formula | System | Group | a [Å] | b [Å] | c [Å] | β [°] | R_{wp} |
| (CH₃NH₃)₂CuCl₄ | monoclinic | (14)P121/a1 | 7.2730(0) | 7.3630(8) | 9.9926(1) | 111.22 | 0.156 |
| (CH₃NH₃)₂CuCl₂Br₂ | orthorhombic | (64) Acam | 7.3378(8) | 7.3379(7) | 19.1870(8) | 90 | 0.135 |
| (CH₃NH₃)₂CuClBr₃ | orthorhombic | (64) Acam | 7.3965(1) | 7.3686(2) | 19.3217(1) | 90 | 0.082 |
| (CH₃NH₃)₂CuCl_{0.5}Br_{3.5} | orthorhombic | (64) Acam | 7.4276(2) | 7.4686(8) | 19.3075(9) | 90 | 0.098 |

While MA₂CuCl₄ is monoclinic, the materials with mixed halides: MA₂CuCl₂Br₂, MA₂CuClBr₃, and MA₂CuCl_{0.5}Br_{3.5} crystallize with an orthorhombic crystal system. The gradual replacement of Cl with Br can be followed by the shift of all the diffraction peaks, except for the 002, towards smaller angles (FIG. 18). This denotes the increase of unit cell dimension due to the larger ionic radius of Br⁻. XRD analysis confirmed the formation of a layered structure, which is illustrated for MA₂CuCl₂Br₂ in FIG. 12B. Cu²⁺ has a highly distorted octahedral coordination CuX₆ (X=Cl, Br), arising from strong Jahn-Teller distortion: two of the 4 Cl—X bonds located in equatorial position (contained within the inorganic plane) are highly elongated compared to the other 4 short Cl—X distances. As shown in the inset of FIG. 12B, the bond length is 2.272(1) Å for two of the equatorial bonds, 2.921(3) Å for the elongated equatorial bonds and 2.436(2) Å for the terminal bonds. Organic and inorganic layers are arranged alternately with the CH₃NH₃⁺ cations interacting through hydrogen bonds with the halogen atoms of the inorganic layer, while the metal atoms are shifted with respect to adjacent layers in a staggered configuration.

These layered perovskites can be easily deposited as films on flat surfaces from a dimethyl sulfoxide (DMSO) solution. MA₂CuCl₂Br₂ and MA₂CuCl_{0.5}Br_{3.5} were selected for further optimizations by virtue of their better stability and improved optical properties, respectively. Thin film XRD patterns of these two films are shown in FIG. 12C and compared to their respective powders. In both the cases, the 001 diffraction peaks are enhanced and the films show a strong preferential orientation toward the 002 direction, with the organic and inorganic layers parallel to the substrate. The annealing conditions were optimized to obtain crystalline, single phase films. Thermogravimetric analysis (TGA) showed the beginning of weight loss at 140° C. for MA₂CuCl₂Br₂ and 120° C. for MA₂CuCl_{0.5}Br_{3.5}, indicating a lower thermal stability for higher Br content and setting an upper limit to the annealing temperature (FIG. 19A-B). The optimal annealing condition was found to be 70° C. for 1 h, since it resulted in highly crystalline perovskite without residual organic precursor. Higher temperatures (100° C.) caused decomposition of the perovskite structure, and lower annealing time (70° C., 30 min) was not sufficient for complete reaction of methylammonium bromide MABr, as shown for MA₂CuCl_{0.5}Br_{3.5} in FIG. 20.

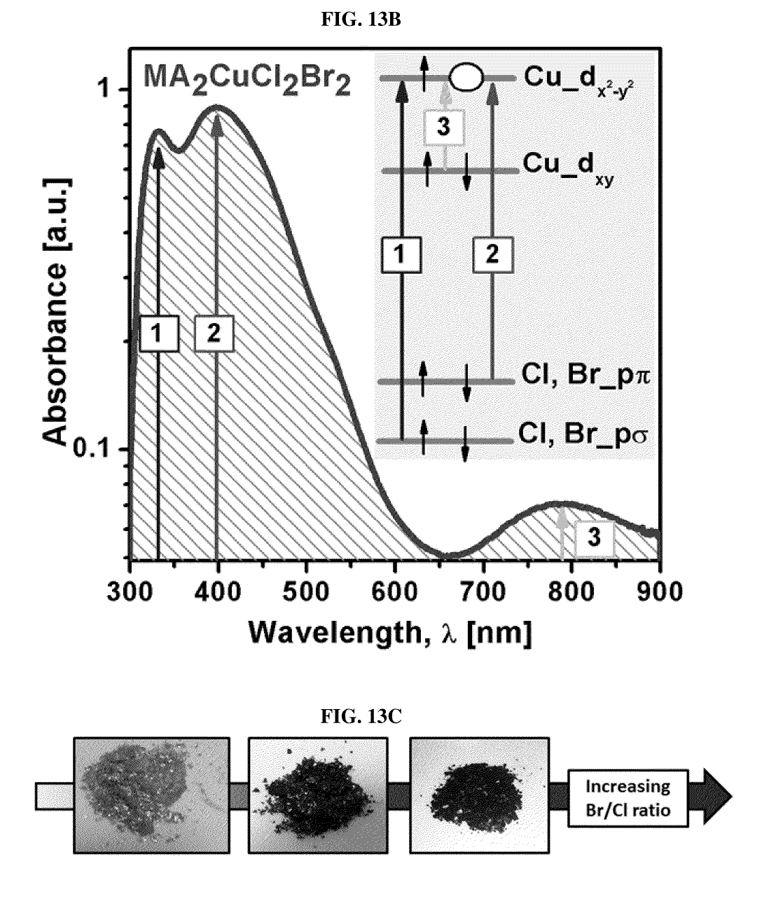

The absorption spectra of the series MA₂CuClₓBr₄₋ₓ, show typical features of copper complexes CuX₄²⁻ in square planar coordination (FIG. 12A), in agreement with the strong Jahn-Teller distortion supported by XRD analysis. Strong bands with absorption coefficients up to 35,000 cm⁻¹ are found below 600 nm. These can be assigned to ligand-to-metal charge transfer (CT) transitions, as previously studied for CuCl₄²⁻ complexes (1 and 2 in FIG. 13B). The position of these bands were found to be highly dependent on the Br content, so that the choice of the Br/Cl ratio allows tuning of the band gap of these materials associated with CT transitions. The band gaps of each material determined from Tauc plots (FIG. 21) were: 2.48 eV (500 nm) for MA₂CuCl₄, 2.12 eV (584 nm) for MA₂CuCl₂Br₂, 1.90 eV (625 nm) for MA₂CuClBr₃, and 1.80 eV (689 nm) for MA₂CuCl_{0.5}Br_{3.5}. The modulation of the band gap appears evident from the color of the powders, which changes from yellow to dark brown with increasing Br/Cl ratio (FIG. 13C). An additional contribution to the absorption is present below the band gap with weaker and broad bands between 700 nm and 900 nm (FIG. 13A). This band may be attributed to d-d transitions (3 in FIG. 13B) within the d levels of copper, and does not shift significantly among the different compounds with varying Br content. The transitions described are schematically shown for MA₂CuCl₂Br₂ in FIG. 13B, for which the energy level of the valence band maximum (VBM) was found to be −4.98 eV by ultraviolet photoelectron spectroscopy (UPS) (FIG. 22).

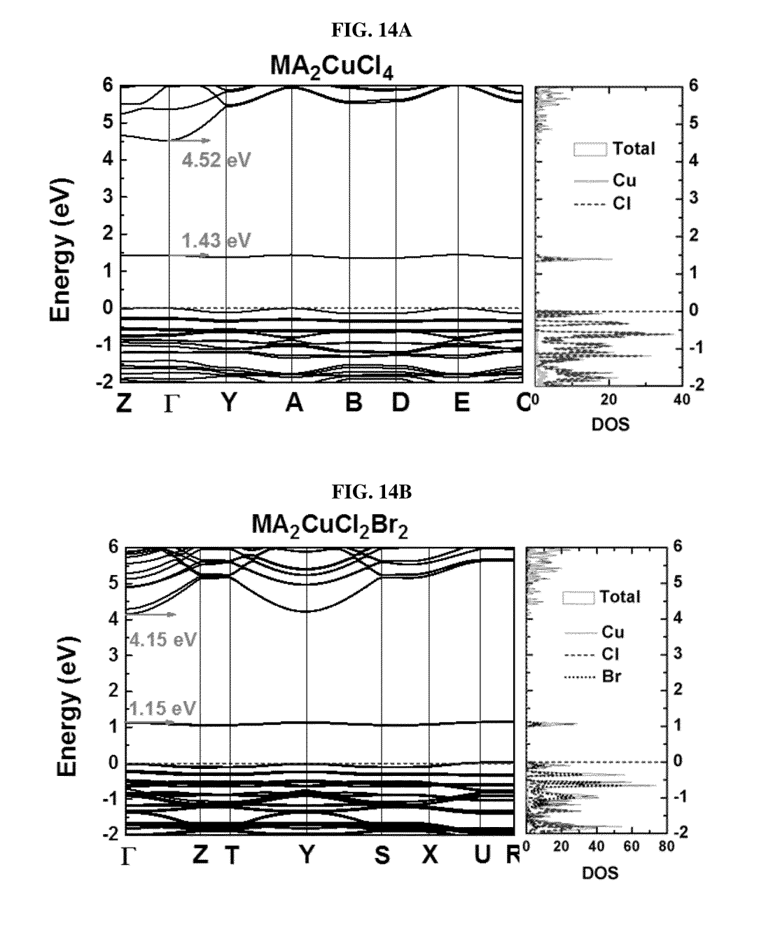

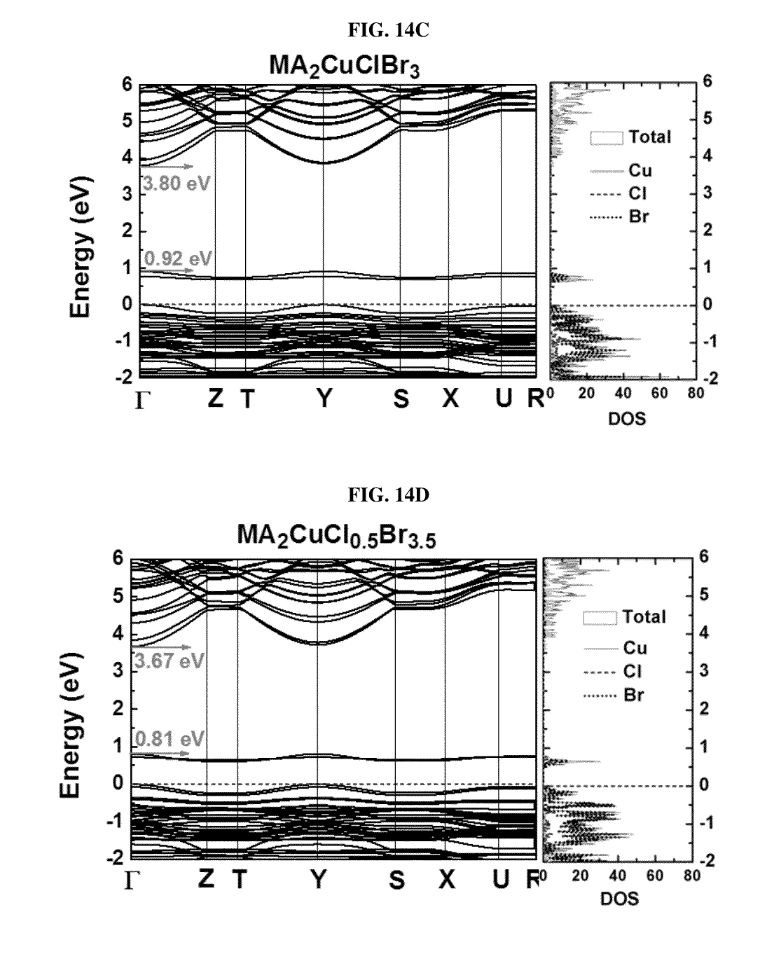

To better understand the electronic properties of these compounds, DFT calculations were performed for the series MA₂CuClₓBr₄₋ₓ, (FIG. 14A-D). Simulations yield excitonic energy gaps of 3.09 eV, 3.00 eV, 2.88 eV and 2.86 eV for MA₂CuCl₄, MA₂CuCl₂Br₂, MA₂CuClBr₃, and MA₂CuCl_{0.5}Br_{3.5}, respectively. These values are in good agreement with the spectral position of the absorption peaks observed experimentally, and the diminishing trend is consistent with the band-gap energies derived from Tauc plot constructions (FIG. 23). These strong bands can be assigned to Cl, Br_pσ→Cu_dₓ_{²}_{-y}_{²} and Cl, Br_pπ→Cu_dₓ_{²}_{-y}_{²} and are therefore associated to ligand-to-metal charge transfer states (FIG. 13B). An additional energy gap is found in the band structure with energy around 1.55 eV for the perovskites with mixed Cl—Br, and at slightly lower energy (1.25 eV) for the full chlorine compound MA₂CuCl₄, as determined from the projected density of state in FIG. 24A-D. These gaps are associated Cu_d_{xs,ys}→Cu_dₓ_{²}_{-y}_{²}, Cu_d_{xy}→Cu_dₓ_{²}_{-y}_{²} and Cu_d_{z}_{²}→Cu_dₓ_{²}_{-y}_{²} transitions and account for the broad bands observed in the absorption spectra between 700 nm and 900 nm, confirming the contribution of d-d transitions from Cu d levels in this region (FIG. 13B). All the materials have a very low density of states close to the band edge, which may reduce probability of electronic transitions.

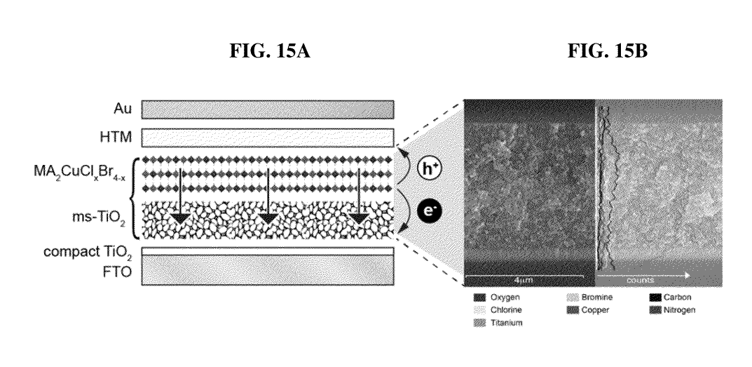

These 2D copper perovskites were integrated in a photovoltaic device architecture by infiltrating mesoporous titania (ms-TiO₂), as shown in the exploded view of the solar cell in FIG. 15A-B. Here, the perovskite is intended to act as a sensitizer, transferring an electron to the titania and hole to the hole transporting material (HTM) upon photoexcitation. Due to the lower absorption coefficient of the material under study compared to the well studied CH₃NH₃PbI₃, a thicker mesoporous layer of 5 μm was used, with the aim to enhance light harvesting from the weaker d-d transition band that extend the active region of the sensitizer to ˜900 nm. The mesoporous layer plays the additional role of breaking continuity of the 2D structure, which favors charge transport within the plane of the film along the continuous inorganic metal halide lattice. When the perovskite is infiltrated within the mesoporous TiO₂ layer, vertical charge transport is facilitated compared to a continuous 2D film, thus improving charge carrier extraction. The perovskite was deposited by spin coating from DMSO solutions, with concentration optimized to obtain the best morphology. Good infiltration of the mesoporous layer was obtained with 1M and 2M solutions, as shown in FIG. 25A-D. In both cases no capping layer was formed on top of the TiO₂. With 1M solutions (FIG. 25A, FIG. 25C), the perovskite was uniformly infiltrated within the mesoporous scaffold, while with 2M solutions (FIG. 25B, FIG. 25D) the perovskite was found to aggregate in big clusters with discontinuous distribution across the film. Due to the better homogeneity, 1M DMSO solutions were selected for device fabrication. The uniform infiltration of MA₂CuCl_{0.5}Br_{3.5} was further confirmed by energy dispersive X-ray (EDX) spectroscopy. The EDX line scan on a cross section of 5 μm mesoporous TiO₂ film shown in FIG. 15B confirms complete penetration of all the elements constitutive of the copper perovskite (Cl, Br, Cu, C, N) till the bottom of the TiO₂ layer.

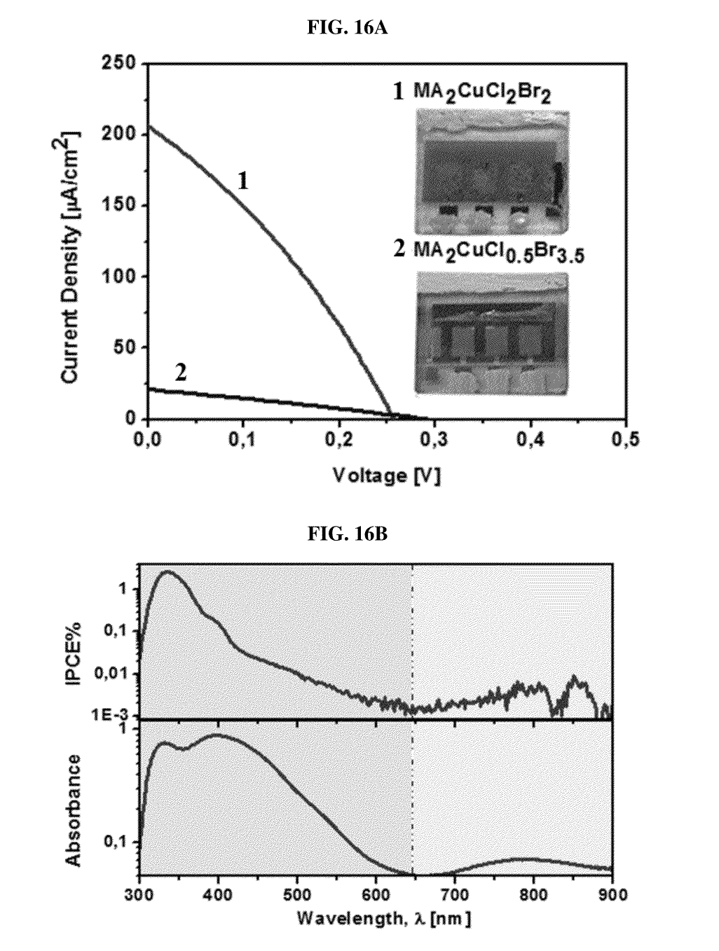

Using spiro-MeOTAD as HTM and 5 μm mesoporous TiO₂, solar cell devices were fabricated with MA₂CuCl₂Br₂ and MA₂CuCl_{0.5}Br_{3.5} and characterized (FIG. 16A). MA₂CuCl₂Br₂ yielded a PCE of 0.017%, with Jsc=216 μA/cm², Voc=256 mV and FF=0.32. Despite the optimized band gap, MA₂CuCl_{0.5}Br_{3.5} gave a much lower power conversion efficiency of 0.0017%, Jsc=21 μA/cm², Voc=290 mV and FF=0.28. Photocurrent measurements were performed on the device based on MA₂CuCl₂Br₂ and confirmed the sensitization action of the perovskite (FIG. 16B). The measurement was performed using a conventional amplitude modulation technique, a Xe lamp as white light source and a monochromator to disperse the light in the 300-900 nm spectral region. Both CT and d-d transitions contribute to the photoresponsivity: while the major photoresponse is due to CT transitions of the perovskite below 640 nm, a weak photocurrent signal between 700 nm and 900 nm is also detected, indicating that d-d transitions may be effectively exploited for photocurrent generation.

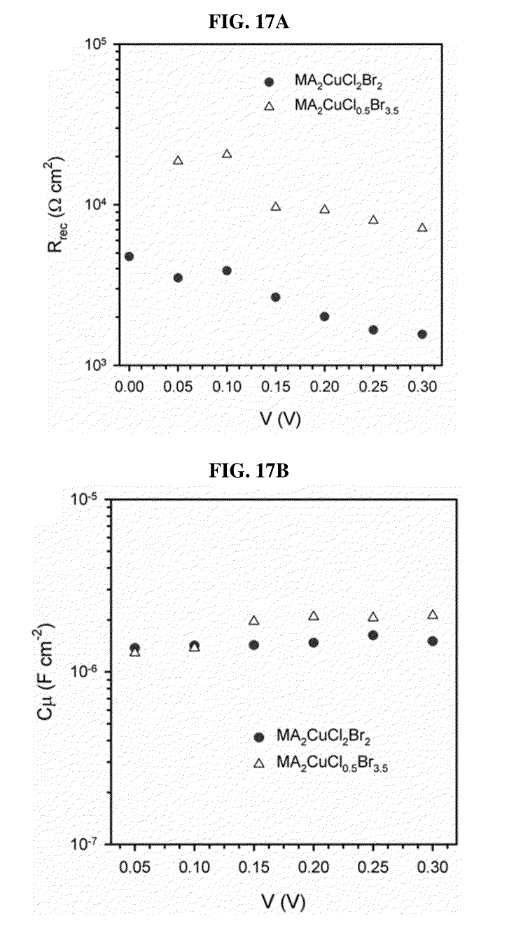

To elucidate the differences between these two samples, impedance spectroscopy (IS) was measured under illumination in the working voltage range of the devices. The IS spectrum (FIG. 28B) features one single arc with high resistivity, suggesting a response dominated by a charge transfer process rather than a charge transport one. From the fittings (following the equivalent circuit shown in the inset of FIG. 28B) it is possible to estimate the series (Rs, FIG. 28A) and parallel resistances as well as the capacitance. The parallel resistance, attributed to the recombination process (R_{rec}), shows a lower value (indicative of higher recombination) for the MA₂CuCl₂Br₂ sample (FIG. 17A). The higher recombination resistance can explain the slightly higher Voc achieved by the MA₂CuCl_{0.5}Br_{3.5} sample, despite its much lower current. It is worth to remark that the large values of the recombination resistance indicate a hampering of a charge transfer process as well, which can be hindering the photogenerated charge injection and therefore having an effect on the low currents achieved.

The values obtained for the capacitance stand in the range of a classical chemical capacitance (C_{μ}) of TiO₂³⁷ (FIG. 17B). This, along with the similar C_{μ} obtained for both analyzed devices, confirms charge injection from the absorber to the mesoporous semiconductor, unlike other perovskite solar cells.

An inverted cell based on flat heterojunction with structure PEDOT:PSS/MA₂CuCl₂Br₂/PCBM was also tested (FIG. 26). Although a higher V_{oc}=415 mV was obtained, the photocurrent was lower (Jsc=342 nA/cm²). This low current density value confirms the importance of breaking continuity of the 2D structure with a mesoporous scaffold to help charge carrier extraction from the perovskite.

Moreover, XPS analysis on thin films revealed the presence of Cu⁺ together with CuCl₂ in the perovskite (FIG. 27A-B). Although the presence of chlorine significantly stabilizes the material, the partial reduction of Cu²⁺ caused by Br⁻ during the annealing could not be completely avoided, and the amount of Cu⁺ was found to increase with the augment in Br content. Copper reduction can introduce anion vacancies in the crystal lattice, which act as electron traps with a negative impact on photocurrent generation. The increased contamination with Cu⁺ with higher Br/Cl ratio indicates a higher concentration of trap states with higher Br content: this can explain why MA₂CuCl_{0.5}Br_{3.5} gave worse efficiency compared to MA₂CuCl₂Br₂, despite the optimized band gap The difference in performance is further supported by the higher recombination resistance measured for MA₂CuCl_{0.5}Br_{3.5}, responsible for a much lower current density with this sensitizer and is possibly a result of the higher Cu⁺ contamination. Moreover, a bad rectification behavior was observed for all the devices, with high dark currents suggesting the presence of high leakage current possibly due to the direct contact between the TiO₂ and HTM, facilitated by the absence of perovskite capping layer over the mesoporous TiO₂. The layered structure of the 2D perovskite in combination with the strong preferential orientation toward the 002 direction may strongly interfere with the charge transport and collection at the electrodes due to the exciton confinement into the inorganic layers. Although the presence of the mesoporous scaffold helps the charge extraction from the perovskite breaking the continuity of the 2D structure, as can be seen comparing the performance with the planar structure, this is not enough to obtain high efficiency devices. Surface engineering and material growth techniques should be applied to achieve a controlled crystallization with orientation favorable to the charge draining within the material and significantly enhance the power conversion efficiency. Further optimization to improve the stability, as well as the charge extraction from the perovskite (new electron and hole acceptor materials to be investigated) are expected to significantly improve the solar cell performance, making 2D copper perovskites a good platform for the development of alternative lead free perovskite for photovoltaic applications.

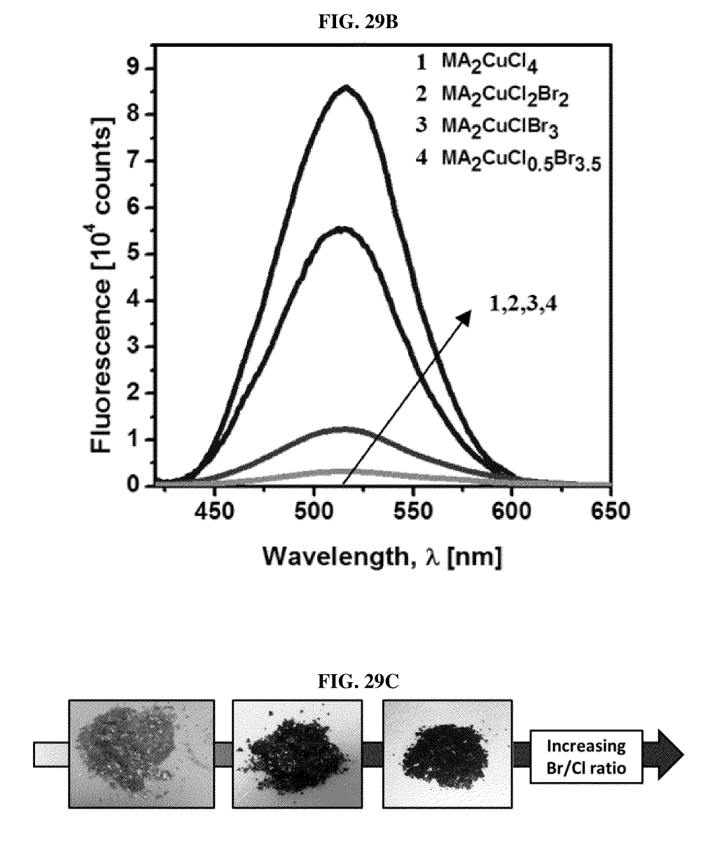

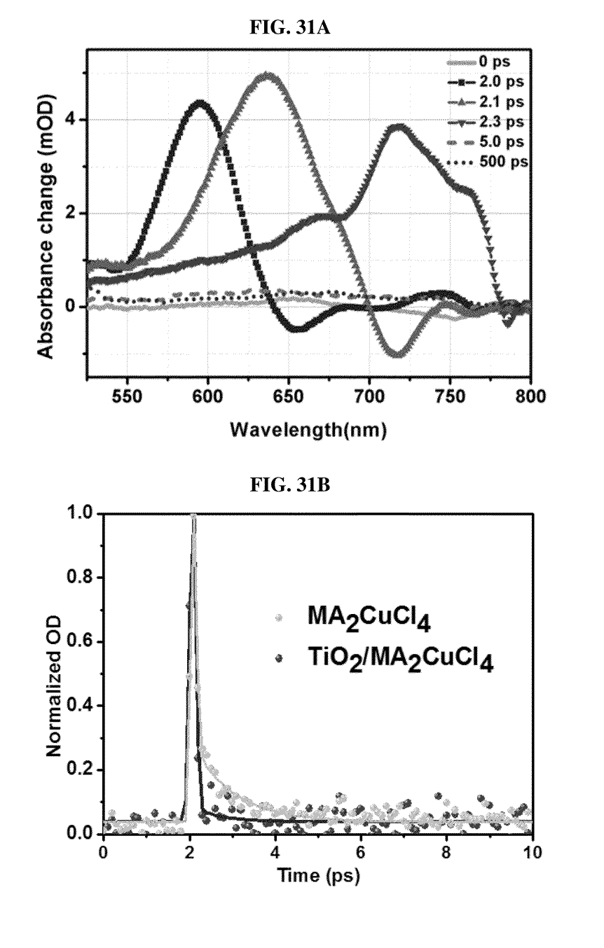

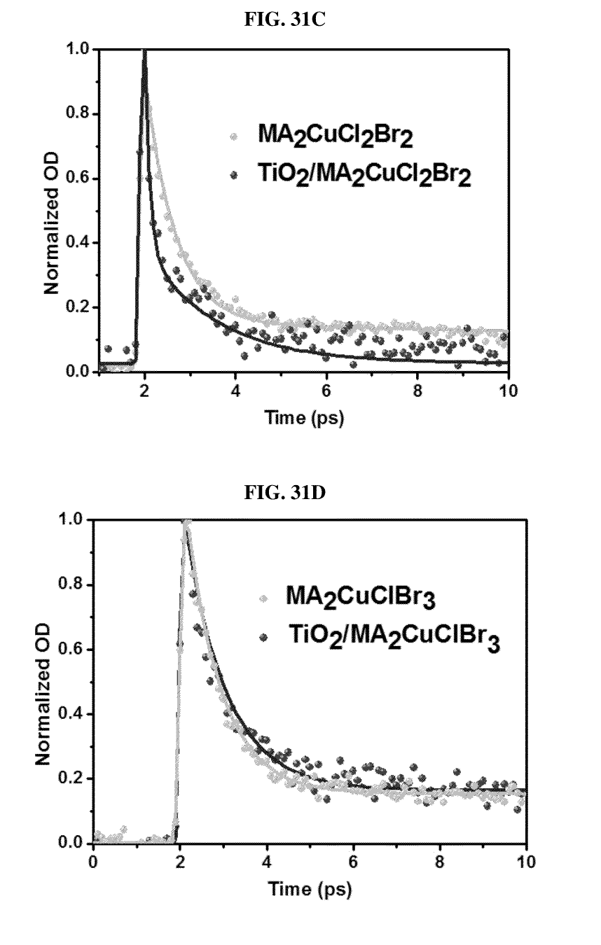

By increasing the Br/Cl ratio in MA₂CuClₓBr₄₋ₓ, it is possible to redshift the absorption due to the charge transfer (CT) transitions up to 700 nm for MA₂CuCl_{0.5}Br_{3.5}. Cu-based d-d transitions further extends the absorption to the NIR region (700-900 nm), as shown in FIG. 31A and FIG. 31C. Upon excitation at 310 nm, the perovskite films showed photoluminescence which peaked around 515 nm with increasing intensity for higher Br/C1 ratio (FIG. 29B). The observed green fluorescence can be assigned to the emission of Cu⁺ ions and suggests that Cu²⁺ is partially reduced during annealing creating emissive trap states in the material. The reduction process is strongly fostered by the presence of bromine, as suggested by the photoluminescence (PL) trend culminating in the stronger emission of MA₂CuCl_{0.5}Br_{3.5}, while chlorine helps to stabilize the Cu²⁺ oxidation state.

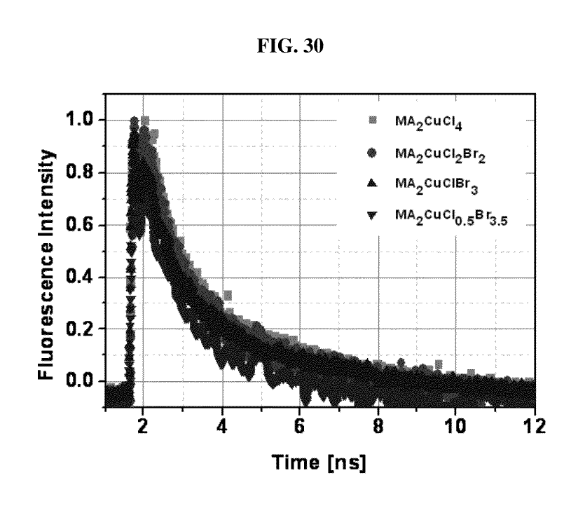

The observed green luminescence may be promising for application in light emitting devices based on lead-free hybrid perovskites. The light emission was deeper investigated by means of time-resolved photoluminescence (TRPL) and in FIG. 30, the normalized PL decays are shown upon excitation at 310 nm and probe at 525 nm. Although the Cl/Br ratio is different for each material, the decay profile is always double exponential with very similar decay times τ1=6.3-4.0 ns and τ2=0.86−1.0 ns. The full result set from the data fitting is shown in Table 2. This behavior suggests again that the photoluminescence is coming from the same emissive species, that is attributed to Cu⁺ trap states, formed as a consequence of Cu²⁺ reduction during the annealing process.

TABLE 2
Time decays from the fitting of time resolved photoluminescence data.

| Material | τ1 [ns] | A1 | τ2 [ns] | A2 |
|---|---|---|---|---|
| MA₂CuCl₄ | 6.3 | 0.24 | 0.86 | 0.76 |
| MA₂CuCl₂Br₂ | 3.5 | 0.23 | 0.52 | 0.77 |
| MA₂CuClBr | 3.8 | 0.27 | 0.60 | 0.73 |
| MA₂CuCl_{0.5}Br_{3.5} | 4.0 | 0.29 | 1.0 | 0.71 |

FIG. 29A shows the transient absorption (TA) spectrum of MA₂CuCl₄ at excitation wavelength of 500 nm as an example. The TA shows a positive signal between 550-800 nm which is probably due to excited state absorption. The dynamics of the perovskites MA₂CuClₓBr₄₋ₓ at 620 nm (FIG. 31B-D) show a very fast decay indicating that more of the 80% of the charges recombine in less than 1 ps in the case of the pure material. This suggests a strong charge confinement in the layered structure that obstruct a long diffusion length. An additional longer component is also present and increases with the increase of the Br/Cl ratio, reaching a decay time >1 ns in the case of MA₂CuClBr₃. These longer-lived species may be correlated to the presence of Cu⁺ trap states, in agreement with the observed photoluminescence and the X-ray Photoelectron spectroscopy (XPS) data. Despite the fast charge recombination, a clear quenching effect was seen for both the short and long-lived components when the perovskite are in contact with TiO₂, indicating that electron transfer from the perovskite is taking place and confirming the photovoltaic effect seen in the mesoporous systems. Table 3 shows the time decays comparison data between perovskite and perovskite/TiO₂ junction.

TABLE 3
Time decays from the fitting of ultrafast transient absorption (TA) data;
comparison between perovskite and perovskite/TiO₂ junction.

| Material | t1 [ps] | A1 | t2 [ps] | A2 | t3 [ps] | A3 |
|---|---|---|---|---|---|---|
| MA₂CuCl₄ | 0.06 | 0.93 | 1.55 | 0.07 | — | — |
| MA₂CuCl₄/TiO₂ | 0.009 | 0.99 | 0.61 | 0.01 | — | — |
| MA₂CuCl₂Br₂ | 0.54 | 0.82 | 6.87 | 0.13 | 480 | 0.05 |
| MA₂CuCl₂Br₂/TiO₂ | 0.04 | 0.81 | 0.87 | 0.17 | 120 | 0.02 |
| MA₂CuClBr₃ | 0.82 | 0.87 | 1040 | 0.13 | — | — |
| MA₂CuClBr₃/TiO₂ | 0.88 | 0.84 | 360 | 0.16 | — | — |

### CONCLUSIONS

The new 2D perovskite series (CH₃NH₃)₂CuCl₄₋ₓBrₓ was studied in detail, and the optical properties were shown to be strongly dependent on the Br/Cl ratio. The absorption is dominated by ligand-to-metal charge transfer transitions Cl, Br_pσ→Cu_dₓ_{²}_{-y}_{²} and Cl, Br_pπ→Cu_dₓ_{²}_{-y}_{²} and their associated band-gap can be tuned increasing the Br content from 2.48 eV (500 nm) for MA₂CuCl₄ to 1.80 eV (689 nm) for MA₂CuCl_{0.5}Br_{3.5}. An additional contribution to the absorption in the region between 700 nm and 900 nm comes from transitions within the d Cu levels (Cu_d_{xs,ys}→Cu_dₓ_{²}_{-y}_{²}, Cu_d_{xy}→Cu_dₓ_{²}_{-y}_{²} and Cu_d_{z}_{²}→Cu_dₓ_{²}_{-y}_{²}). These perovskites can be easily deposited in thin films by spin coating, forming highly oriented films toward the 002 direction. Despite the redshift of the absorption increasing the Br/Cl ratio, bromine showed a tendency to reduce Cu²⁺ to Cu⁺ during annealing, and the presence of chlorine was found to be essential to stabilize the structure. Solar cell devices based on copper perovskite were realized: the uniform infiltration of mesoporous titania with 2D copper perovskites was achieved and power conversion efficiency of 0.017% was obtained using MA₂CuCl₂Br₂ as sensitizer. Besides, both the CT and d-d transitions were shown to actively contribute to the photocurrent generation. The partial copper reduction caused by bromine is responsible for the introduction of anion vacancies, which can act as electron traps, strongly limiting the cell efficiency. Moreover, charge extraction at the interface 2D perovskite/TiO₂ is an additional limiting factor. This is the first example of synthesis and integration of a 2D copper perovskite light harvester in photovoltaic devices, opening up a viable alternative route to lead-free perovskite cells.

Significant increase of the photo conversion efficiency can be expected with the improvement of electron injection from the perovskite toward the electron acceptor material. This can be done substituting the TiO₂ with materials having a higher conduction band (such as SrTiO₃) and with the functionalization of the electron acceptor material with PCBM or any of its derivatives. Moreover, the control of the crystallization of the perovskite to achieve different preferential orientations more favorable to the electron flow within the cell will further improve the efficiency. Doping strategies, such as mixed metal systems and the introduction of fluorine, should prevent the reduction of Cu²⁺ avoiding the formation of trap states, with further gain in the photocurrent generation.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

By “about” in relation to a given numberical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples. In addition, where features or aspects of the invention are described in terms of Markush groups, those skilled in the art will recognize that the invention is also thereby described in terms of any individual member or subgroup of members of the Markush group.

### REFERENCES

1. Kamat, P. V. Organometal Halide Perovskites for Transformative Photovoltaics. Journal of the American Chemical Society 2014, 136, 3713-3714.
2. Kim, H.-S.; Im, S. H.; Park, N.-G. Organolead Halide Perovskite: New Horizons in Solar Cell Research. The Journal of Physical Chemistry C 2014, 118, 5615-5625.
3. Burschka, J.; Pellet, N.; Moon, S.-J.; Humphry Baker, R.; Gao, P.; Nazeeruddin, M.; Graetzel, M. Sequential deposition as a route to high-performance perovskite-sensitized solar cells. Nature 2013, 499, 316-319.
4. Green, M. A.; Emery, K.; Hishikawa, Y.; Warta, W.; Dunlop, E. D. Solar cell efficiency tables (version 44). Progress in Photovoltaics: Research and Applications 2014, 22, 701-710.
5. Liu, D.; Kelly, T. L. Perovskite solar cells with a planar heterojunction structure prepared using room-temperature solution processing techniques. Nat Photon 2014, 8, 133-138.
6. Liu, M.; Johnston, M. B.; Snaith, H. J. Efficient planar heterojunction perovskite solar cells by vapour deposition. Nature 2013, 501, 395-398.
7. Hu, Q.; Wu, J.; Jiang, C.; Liu, T.; Que, X.; Zhu, R.; Gong, Q. Engineering of Electron-Selective Contact for Perovskite Solar Cells with Efficiency Exceeding 15%. ACS Nano 2014.
8. Boix, P. P.; Nonomura, K.; Mathews, N.; Mhaisalkar, S. G. Current progress and future perspectives for organic/inorganic perovskite solar cells. Materials Today 2014, 17, 16-23.
9. Xing, G.; Mathews, N.; Lim, S.; Yantara, N.; Liu, X.; Sabba, D.; GrÃ [symbol] zel, M.; Mhaisalkar, S.; Sum, T. Low-temperature solution-processed wavelength-tunable perovskites for lasing. Nature Materials 2014, 13, 476-480.
10. Xing, G.; Mathews, N.; Sun, S.; Lim, S.; Lam, Y.; GrÃ [symbol] zel, M.; Mhaisalkar, S.; Sum, T.; Gratzel, M. Long-Range Balanced Electron- and Hole-Transport Lengths in Organic-Inorganic CH3NH3PbI3. Science 2013, 342, 344-347.
11. Zhou, H.; Chen, Q.; Li, G.; Luo, S.; Song, T.-b.; Duan, H.-S.; Hong, Z.; You, J.; Liu, Y.; Yang, Y. Interface engineering of highly efficient perovskite solar cells. Science 2014, 345, 542-546.
12. Gao, P.; Gratzel, M.; Nazeeruddin, M. K. Organohalide lead perovskites for photovoltaic applications. Energy & Environmental Science 2014, 7, 2448-2463.
13. Snaith, H. Perovskites: The Emergence of a New Era for Low-Cost, High-Efficiency Solar Cells. The journal of physical chemistry letters 2013, 4, 3623-3630.
14. Green, M. A.; Ho-Baillie, A.; Snaith, H. J. The emergence of perovskite solar cells. Nat Photon 2014, 8, 506-514.
15. You, J.; Hong, Z.; Yang, Y.; Chen, Q.; Cai, M.; Song, T.-B.; Chen, C.-C.; Lu, S.; Liu, Y.; Zhou, H.; Yang, Y. Low-Temperature Solution-Processed Perovskite Solar Cells with High Efficiency and Flexibility. ACS Nano 2014, 8, 1674-1680.
16. Eperon, G. E.; Burlakov, V. M.; Goriely, A.; Snaith, H. J. Neutral Color Semitransparent Microstructured Perovskite Solar Cells. ACS Nano 2013, 8, 591-598.
17. Li, Y.; Moon, K.-s.; Wong, C. P. Electronics Without Lead. Science 2005, 308, 1419-1420.
18. Panda, P. K. Review: environmental friendly lead-free piezoelectric materials. J Mater Sci 2009, 44, 5049-5062.
19. Goyer, R. A. Lead toxicity: current concerns. Environmental health perspectives 1993, 100, 177-87.
20. Slaveykova, V. I.; Wilkinson, K. J. Physicochemical aspects of lead bioaccumulation by Chlorella vulgaris. Environmental science & technology 2002, 36, 969-75.
21. Kumar, M. H.; Dharani, S.; Leong, W. L.; Boix, P. P.; Prabhakar, R. R.; Baikie, T.; Shi, C.; Ding, H.; Ramesh, R.; Asta, M.; Graetzel, M.; Mhaisalkar, S. G.; Mathews, N. Lead-Free Halide Perovskite Solar Cells with High Photocurrents Realized Through Vacancy Modulation. Advanced Materials 2014, 1-6.
22. Hao, F.; Stoumpos, C. C.; Cao, D. H.; Chang, R. P. H.; Kanatzidis, M. G. Lead-free solid-state organic-inorganic halide perovskite solar cells. Nat Photon 2014, 8, 489-494.
23. Chung, I.; Lee, B.; He, J.; Chang, R. P. H.; Kanatzidis, M. G. All-solid-state dye-sensitized solar cells with high efficiency. Nature 2012, 485, 486-489.
24. Noel, N. K.; Stranks, S. D.; Abate, A.; Wehrenfennig, C.; Guarnera, S.; Haghighirad, A.-A.; Sadhanala, A.; Eperon, G. E.; Pathak, S. K.; Johnston, M. B.; Petrozza, A.; Herz, L. M.; Snaith, H. J. Lead-free organic-inorganic tin halide perovskites for photovoltaic applications. Energy & Environmental Science 2014.
25. Cheng, Z.; Lin, J. Layered organic-inorganic hybrid perovskites: structure, optical properties, film preparation, patterning and templating engineering. CrystEngComm 2010, 12, 2646-2662.
26. Moodenbaugh, A. R.; Suenaga, M.; Folkerts, T. J.; Shelton, R. N.; Xu, Y. Superconducting properties of La_{2-x}Ba_{x}CuO_{4}. Physical review. B, Condensed matter 1988, 38, 4596-4600.
27. Mitzi, D. B. Hybrid Organic-Inorganic Electronics. In Functional Hybrid Materials, Wiley-VCH Verlag GmbH & Co. KGaA: 2005; pp 347-386.
28. Mitzi, D. B. Templating and structural engineering in organic-inorganic perovskites. Journal of the Chemical Society, Dalton Transactions 2001, 1-12.
29. Mitzi, D. B. Synthesis, Structure, and Properties of Organic-Inorganic Perovskites and Related Materials. In Progress in Inorganic Chemistry, John Wiley & Sons, Inc.: 2007; pp 1-121.
30. Greenwood, N. N.; Earnshaw, A. Chemistry of the elements. Pergamon Press: 1984.
31. Willett, R.; Place, H.; Middleton, M. Crystal structures of three new copper(II) halide layered perovskites: structural, crystallographic, and magnetic correlations. Journal of the American Chemical Society 1988, 110, 8639-8650.
32. Snively, L. O.; Drumheller, J. E.; Emerson, K. Magnetic susceptibility of 1,4-butanediammonium tetrachlorocuprate. Physical Review B 1981, 23, 6013-6017.
33. de Jongh, L. J. Experiments on simple magnetic model systems. Journal of Applied Physics 1978, 49, 1305-1310.
34. Estes, W. E.; Losee, D. B.; Hatfield, W. E. The magnetic properties of several quasi two-dimensional Heisenberg layer compounds: A new class of ferromagnetic insulators involving halocuprates. The Journal of Chemical Physics 1980, 72, 630-638.
35. Jaffe, A.; Karunadasa, H. I. Lithium Cycling in a Self-Assembled Copper Chloride-Polyether Hybrid Electrode. Inorganic Chemistry 2014, 53, 6494-6496.
36. Desjardins, S. R.; Penfield, K. W.; Cohen, S. L.; Musselman, R. L.; Solomon, E. I. Detailed absorption, reflectance, and UV photoelectron spectroscopic and theoretical studies of the charge-transfer transitions of tetrachlorocuprate(2−) ion: correlation of the square-planar and the tetrahedral limits. Journal of the American Chemical Society 1983, 105, 4590-4603.
37. Fabregat-Santiago, F.; Garcia-Belmonte, G.; Mora-Sero, I.; Bisquert, J. Characterization of nanostructured hybrid and organic solar cells by impedance spectroscopy. Physical Chemistry Chemical Physics 2011, 13, 9083-9118.
38. Dharani, S.; Dewi, H. A.; Prabhakar, R. R.; Baikie, T.; Shi, C.; Yonghua, D.; Mathews, N.; Boix, P. P.; Mhaisalkar, S. G. Incorporation of Cl into sequentially deposited lead halide perovskite films for highly efficient mesoporous solar cells. Nanoscale 2014, 6, 13854-13860.
39. Von Dreele, R. B.; Louer, D.; Scardi, P.; McCusker, L. B.; Von-Dreele, R. B.; Cox, D. E.; Louer, D. Rietveld refinement guidelines. Journal of applied crystallography 1999, 32, 36-50.
40. Cheary, R. W.; Coelho, A. A fundamental parameters approach to X-ray line-profile fitting. Journal of Applied Crystallography 1992, 25, 109-121.
41. Giannozzi, P.; Baroni, S.; Bonini, N.; Calandra, M.; Car, R.; Cavazzoni, C.; Ceresoli, D.; Chiarotti, G. L.; Cococcioni, M.; Dabo, I.; Dal Corso, A.; de Gironcoli, S.; Fabris, S.; Fratesi, G.; Gebauer, R.; Gerstmann, U.; Gougoussis, C.; Kokalj, A.; Lazzeri, M.; Martin-Samos, L.; Marzari, N.; Mauri, F.; Mazzarello, R.; Paolini, S.; Pasquarello, A.; Paulatto, L.; Sbraccia, C.; Scandolo, S.; Sclauzero, G.; Seitsonen, A. P.; Smogunov, A.; Umari, P.; Wentzcovitch, R. M. QUANTUM ESPRESSO: a modular and open-source software project for quantum simulations of materials. J Phys-Condens Mat 2009, 21.
42. Perdew, J. P.; Burke, K.; Ernzerhof, M. Generalized gradient approximation made simple. Phys Rev Lett 1996, 77, 3865-3868.
43. Garrity, K. F.; Bennett, J. W.; Rabe, K. M.; Vanderbilt, D. Pseudopotentials for high-throughput DFT calculations. Comp Mater Sci 2014, 81, 446-452.
44. Dudarev, S. L.; Botton, G. A.; Sutton, A. P. Electron energy loss spectra and the structural stability of oxides with strongly correlated electrons, ELECTRON MICROSCOPY 1998, VOL 3. 1998, 613-614.

1. A copper-based perovskite material comprising a general formula (I), (II), or (III),
(A1)ₐ(A2)_{b}Cu(X1)_{c}(X2)_{d}(X3)ₑ(X4)_{f} (I)
(A1)ₐ(A2)_{b}Cu(X1)_{c}(X2)_{d}(X3)ₑ(X4)_{f}(X5)_{g}(X6)ₕ (II)
(A1)ₐCu(X1)_{b}(X2)_{c}(X3)_{d} (III)
wherein in formula (I):
A1 and A2 are independently selected from the group consisting of an organic ammonium cation derived from RNH₃ wherein R is an aliphatic group, a cyclic group, or an aromatic group; an organic cation derived from an aromatic compound, and an inorganic cation comprising Li⁺, Na⁺, K⁺, Rb⁺ or Cs⁺;
X1, X2, X3, and X4 are independently a halide selected from the group consisting of Cl⁻, Br⁻, F⁻ and I⁻, or an oxygen-halide;
a+b=2;
c+d+e+f=4;
wherein in formula (II):
A1 and A2 are independently selected from the group consisting of an organic ammonium cation derived from RNH₃ wherein R is an aliphatic group, a cyclic group, or an aromatic group; an organic cation derived from an aromatic compound, and an inorganic cation comprising Li⁺, Na⁺, K⁺, Rb⁺ or Cs⁺;
X1, X2, X3, X4, X5, and X6 are independently a halide selected from the group consisting of Cl⁻, Br⁻, F⁻ and I⁻, or an oxygen-halide;
a+b=2;
c+d+e+f+g+h=6;
wherein in formula (III):
A1 is selected from the group consisting of an organic ammonium cation derived from RNH₃ wherein R is an aliphatic group, a cyclic group, or an aromatic group; an organic cation derived from an aromatic compound, and an inorganic cation comprising Li⁺, Na⁺, K⁺, Rb⁺ or Cs⁺;
X1, X2, and X3 are independently a halide selected from the group consisting of Cl⁻, Br⁻, F⁻ and I⁻, or an oxygen-halide;
a=1;
b+c+d=3.

2. The copper-based perovskite material according to claim 1, wherein in formula (I), X1, X2, X3, and X4 are the same, or in formula (II), X1, X2, X3, X4, X5, and X6 are the same, or in formula (III), X1, X2, and X3 are the same.

3. The copper-based perovskite material according to claim 2, wherein formula (I) is (A1)ₐ(A2)_{b}CuCl₄, or formula (II) is (A1)ₐ(A2)_{b}CuCl₆, or formula (III) is (A1)ₐCuCl₃.

4. The copper-based perovskite material according to claim 1, wherein in formula (I), at least one of X1, X2, X3, and X4 is different from the rest, or in formula (II), at least one of X1, X2, X3, X4, X5, and X6 is different from the rest, or in formula (III), at least one of X1, X2, and X3 is different from the rest.

5. The copper-based perovskite material according to claim 4, wherein formula (I) is (A1)ₐ(A2)_{b}CuCl_{0.5}Br_{3.5}, (A1)ₐ(A2)_{b}CuClBr₃, (A1)ₐ(A2)_{b}CuCl_{1.5}Br_{2.5}, (A1)ₐ(A2)_{b}CuCl₂Br₂, (A1)ₐ(A2)_{b}CuCl_{2.5}Br_{1.5}, (A1)ₐ(A2)_{b}CuCl₃Br, or (A1)ₐ(A2)_{b}CuCl_{3.5}Br_{0.5}, or formula (II) is (A1)ₐ(A2)_{b}CuCl_{0.5}Br_{5.5}, (A1)ₐ(A2)_{b}CuClBr₅, (A1)ₐ(A2)_{b}CuCl_{1.5}Br_{4.5}, (A1)ₐ(A2)_{b}CuCl₂Br₄, (A1)ₐ(A2)_{b}CuCl_{2.5}Br_{3.5}, (A1)ₐ(A2)_{b}CuCl₃Br₃, (A1)ₐ(A2)_{b}CuCl_{3.5}Br_{2.5}, (A1)ₐ(A2)_{b}CuCl₄Br₂, (A1)ₐ(A2)_{b}CuCl₄₅Br_{1.5}, (A1)ₐ(A2)_{b}CuCl₅Br, or (A1)ₐ(A2)_{b}CuCl_{5.5}Br_{0.5}.

6. The copper-based perovskite material according to claim 1, wherein R is a substituted or unsubstituted alkyl or a substituted or unsubstituted arylalkyl group.

7. The copper-based perovskite material according to claim 6, wherein the organic ammonium cation is CH₃NH₃⁺ and C₂H₅NH₃⁺, phenethylammonium, 2,2-(ethylenedioxy)bis(ethylammonium), or N-(3-aminopropyl)imidazole.

8. The copper-based perovskite material according to claim 1, wherein the organic cation is tropylium ion [C₇H₇]⁺.

9. The copper-based perovskite material according to claim 1, wherein in formula (I) or (II), A1 and A2 are the same.

10. The copper-based perovskite material according to claim 9, wherein in formula (I) or (II), A1 and A2 are CH₃NH₃⁺.

11. The copper-based perovskite material according to claim 1, wherein in formula (I) or (II), A1 and A2 are different.

12. The copper-based perovskite material according to claim 11, wherein in formula (I) or (II), A1 is CH₃NH₃⁺ and A2 is C₂H₅NH₃⁺.

13. The copper-based perovskite material according to claim 1, wherein formula (III) is CsCuCl₃.

14. The copper-based perovskite material according to claim 1, wherein in formula (I), Cu is doped with a transition metal in the +2 oxidation state, or in formula (II), Cu is doped with a transition metal in the +4 oxidation state.

15. An optoelectronic device, comprising:
an active layer comprising a copper-based perovskite material according to claim 1, wherein the active layer is arranged in between a charge carrier transporting layer and a charge carrier blocking layer;
a conducting substrate; and
a current collector.

16. The optoelectronic device according to claim 15, wherein the active layer comprises a thin film of the copper-based perovskite material.

17. The optoelectronic device according to claim 15, wherein the active layer comprises the copper-based perovskite material comprised in the pores of a mesoporous semiconductor layer.

18. The optoelectronic device according to claim 15, wherein the active layer is arranged in between a hole transporting layer and a hole blocking layer.

19. The optoelectronic device according to claim 15, wherein the active layer is arranged in between an electron transporting layer and an electron blocking layer.

20. A method of synthesizing a copper-based perovskite material according to claim 1, the method comprising:
dissolving a precursor of the organic ammonium cation, organic cation or inorganic cation and copper halide or a Cu²⁺ based precursor in an alcohol;
heating the mixture for a period of time;
crystallizing the mixture in an ice-bath overnight to obtain the copper-based perovskite material crystals;
filtering the crystals; and
drying the crystals in an oven.

21. A method of fabricating an optoelectronic device according to claim 15, the method comprising:
arranging an active layer comprising a copper-based perovskite material according to claim 1 in between a charge carrier transporting layer and a charge carrier blocking layer;
arranging a conducting substrate in contact with the charge carrier blocking layer; and
arranging a current collector in contact with the charge carrier transporting layer.
